(19) United States
(12) Patent Application Publication
(10) Pub. No.: US 2008/0315185 A1
(43) Pub. Date: Dec. 25, 2008

(54) Photodetector

(76) Inventor: Yasushi Araki, Kanagawa (JP)

Correspondence Address: SUGHRUE-265550, 2100 PENNSYLVANIA AVE. NW, WASHINGTON, DC, 20037-3213, US

(21) Appl. No.: 10/593,960

(22) PCT Filed: Mar. 18, 2005
(86) PCT No.: PCT/JP2005/005608

§ 371 Date: Sep. 22, 2006

(30) Foreign Application Priority Data
Mar. 22, 2004 (JP) 2004-082002

(51) Int. Cl. H01L 31/0256

(52) U.S. Cl. 257/40; 257/E31.003

(57) ABSTRACT

A photodetector comprising: at least one electron transporting organic material; and at least one hole transporting material, wherein said at least one electron transporting organic material has an ionization potential of more than 5.5 eV.

### TECHNICAL FIELD

The present invention relates to a photodetector and an imaging device.

### BACKGROUND ART

A photodetector capable of converting light to electric signal plays an extremely important role as a fundamental element in an imaging device, and exerts a great influence on the characteristic properties of the imaging device. With the spread of digital cameras and mobile phones, active research and development have been conducted on the imaging device, resulting in extremely highly developed imaging devices. However, background imaging devices having a photoelectric converting portion within a Si wafer have a restriction as to the area of light-receiving face because all elements be formed within the substrate, thus having a poor external quantum efficiency. Therefore, it has been desired to develop a light-receiving portion having a high light-utilizing efficiency. As a structure of an imaging device having a high light-utilizing efficiency, there can be considered a structure described in JP-A-58-103165. The light-utilizing efficiency can be improved by providing a photoelectric converting portion on a signal-transmitting substrate as described therein, but it has been extremely difficult to prepare a photoelectric converting portion having an enough high performance to be practically usable.

### DISCLOSURE OF THE INVENTION

An object of the invention is to develop a photodetector, which can be easily formed on any substrate and shows a high quantum efficiency, and an imaging device excellent in the usability of the lights, having a number of photoelectric converting portions and a number of pixels.

The object of the invention has been attained by the following means.

(1) A photodetector comprising:

at least one electron transporting organic material; and

at least one hole transporting material,

wherein said at least one electron transporting organic material has an ionization potential of more than 5.5 eV.

(2) A photodetector comprising:

at least one electron transporting organic material; and

at least one hole transporting material,

wherein an ionization potential of said at least one electron transporting organic material is larger than an energy necessary for the highest-level electron of said at least one hole transporting material to be taken out to a vacuum infinite far point.

(3) A photodetector as described in (2) above,

wherein said at least one hole transporting material is at least one hole transporting organic material,

wherein an ionization potential of said at least one electron transporting organic material is more than an ionization potential of said at least one hole transporting organic material.

(4) The photodetector as described in any of (1) to (3) above,

wherein the ionization potential of said at least one electron transporting organic material is more than 6.0 eV.

(5) The photodetector as described in any of (1) to (4) above,

wherein said at least one electron transporting organic material is a compound represented by formula (I):

LA)ₘ Formula (I)

wherein m represents an integer of 2 or more;

L represents a linking group; and

each of A's independently represents a hetero ring group where at least two aromatic hetero rings are condensed to each other, and A's are the same or different.

(6) The photodetector as described in any of (1) to (5) above,

wherein said at least one electron transporting organic material is a compound represented by formula (III):

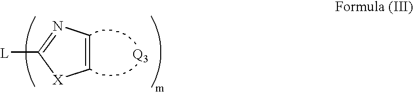

wherein in represents an integer of 2 or more;

L represents a linking group;

each of X's independently represents O, S, Se, Te or N—R;

R represents a hydrogen atom, an aliphatic hydrocarbon group, an aryl group or a hetero ring group; and

each of Q₃'s independently represents an atomic group necessary for forming an aromatic hetero ring.

(7) The photodetector as described in any of (1) to (6) above,

wherein said at least one electron transporting organic material is a compound represented by formula (V):

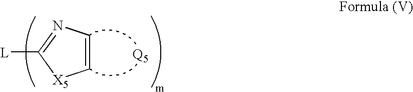

wherein m represents an integer of 2 or more;

L represents a linking group;

each of X₅'s independently represents O, S or N—R;

R represents a hydrogen atom, an aliphatic hydrocarbon group, an aryl group or a hetero ring group; and

each of Q₅'s independently represents an atomic group necessary for forming a 6-membered nitrogen-containing aromatic hetero ring.

(8) The photodetector as described in any of (1) to (7) above,

wherein said at least one electron transporting organic material is a compound represented by formula (VII):

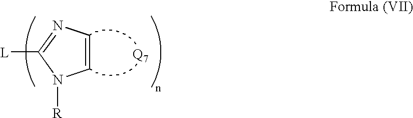

wherein n represents an integer of 2 to 8;

L represents a linking group;

each of R's independently represents a hydrogen atom, an aliphatic hydrocarbon group, an aryl group or a hetero ring group; and

each of Q₇'s independently represents an atomic group necessary for forming a 6-membered nitrogen-containing aromatic hetero ring.

(9) The photodetector as described in any of (1) to (8) above,

wherein said at least one electron transporting organic material is a compound represented by formula (VIII):

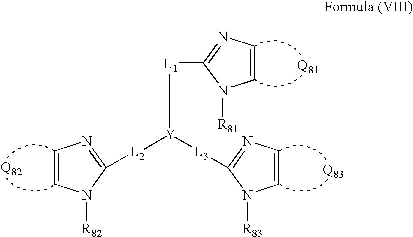

wherein Q₈₁, Q₈₂ and Q₈₃ each independently represents an atomic group necessary for forming a 6-membered nitrogen-containing aromatic hetero ring;

R₈₁, R₈₂ and R₈₃ each independently represents a hydrogen atom, an aliphatic hydrocarbon group, an aryl group or a hetero ring group;

L₁, L₂ and L₃ each independently represents a linking group; and

Y represents a nitrogen atom or a 1,3,5-benzenetriyl group.

(10) The photodetector as described in any of (1) to (9) above,

wherein said at least one electron transporting organic material is a compound represented by formula (IX):

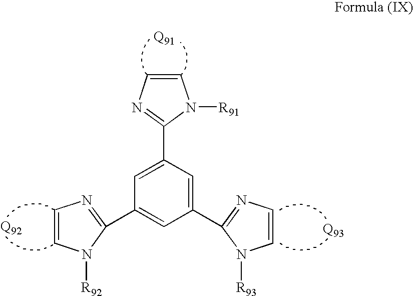

wherein Q₉₁, Q₉₂ and Q₉₃ each independently represents an atomic group necessary for forming a 6-membered nitrogen-containing aromatic hetero ring; and

R₉₁, R₉₂ and R₉₃ each independently represents a hydrogen atom, an aliphatic hydrocarbon group, an aryl group or a hetero ring group.

(11) The photodetector as described in any of (1) to (5) above,

wherein said at least one electron transporting organic material is a compound represented by formula (XI):

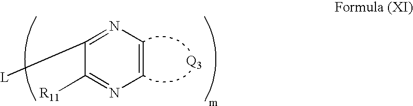

wherein m represents an integer of 2 or more;

L represents a linking group;

each of Q₃'s independently represents an atomic group necessary for forming an aromatic hetero ring group; and

each of R₁₁'s independently represents a hydrogen atom or a substituent.

(12) The photodetector as described in any of (1) to (11) above, further comprising:

at least one transparent electrode; and

at least one electrode,

wherein said at least one electron transporting organic material is interposed between said at least one transparent electrode and said at least one electrode.

(13) The photodetector as described in any of (1) to (12) above, further comprising:

at least one transparent electrode; and

at least one electrode,

wherein said at least one electron transporting organic material and said at least one hole transporting material are interposed between said at least one transparent electrode and said at least one electrode.

(14) The photodetector as described in any of (3) to (12) above, further comprising:

at least one transparent electrode; and

at least one electrode,

wherein said at least one electron transporting organic material and said at least one hole transporting organic material are interposed between said at least one transparent electrode and said at least one electrode.

(15) The photodetector as described in any of (1), (2) and (13) above,

wherein said at least one electron transporting organic material is deposited in vacuum.

(16) The photodetector as described in any of (3) to (12) and (14) above,

wherein at least one of said at least one electron transporting organic material and said at least one hole transporting organic material is deposited in vacuum.

(17) An imaging device comprising a photodetector as described in any of (1) to (16) above.

(18) The imaging device as described in (17) above, further comprising:

a substrate;

a first layer comprising a first photodetector; and

a second layer comprising a second photodetector.

(19) The imaging device as described in (17) above, further comprising:

a substrate;

a first layer comprising a first photodetector;

a second layer comprising a second photodetector; and

a third layer comprising a third photodetector.

(20) The imaging device as described in (19) above,

wherein the first photodetector comprises a blue light photodetector; the second photodetector comprises a green light photodetector; and the third photodetector comprises a red light photodetector.

### BRIEF DESCRIPTION OF THE DRAWING

FIG. 1 is a view showing a schematic constitution of a CCD imaging device to be used in an embodiment of the invention, with (A) being a plane, and (B) being a cross-sectional view taken on line IB-IB;

FIG. 2 is a cross-sectional view taken on line IB-IB showing a schematic constitution of a CCD imaging device to be used in an embodiment of the invention;

FIG. 3 is a plane view showing the constitution of the solid state imaging device in accordance with the embodiment of the invention; and

FIG. 4 is a view showing the constitution of a contact hole portion in the embodiment, with (A) being a plane, and (B) being a cross-sectional view taken on line IVB-IVB.

101 denotes a first layer (polysilicon electrode), 102 denotes a second layer (polysilicon electrode), 105 denotes a light-receiving portion, 106 denotes a charge transfer channel, 107 denotes a read-out gate, 108 denotes an element-separating region (channel stop), 109 denotes an insulating membrane, each of 111, 112, 113 and 114 denotes a transfer electrode (polysilicon electrode), 122 denotes a vertical charge transfer portion (VCCD), 123 denotes a horizontal charge transfer portion (HCCD), 124 denotes a signal-reading circuit, 125 denotes a metal wiring, 126 denotes a contact hole, 127 denotes a polysilicon electrode, 129 denotes an insulating membrane and 130 denotes a wiring pattern.

### BEST MODE FOR CARRYING OUT THE INVENTION

The photodetector of the invention has at least one electron transporting organic material and at least one hole transporting material, and it is extremely preferred for the electron transporting organic material to have an ionization potential of more than 5.5 eV. The ionization potential is, more preferably 5.8 eV or more, still more preferably 6.0 eV or more, yet more preferably 6.2 eV or more, yet more preferably 6.5 eV or more, yet more preferably 6.8 eV or more. That is, the larger the ionization potential, the more preferred. Because the larger ionization potential serves to improve hole-blocking ability and increase charge-separating efficiency. Thus, it is preferred in the invention that the ionization potential of the electron transporting organic material is larger than the energy necessary for the highest-level electron of the hole transporting material to be taken out to the vacuum infinite far point. The term “energy necessary for the highest-level electron of the hole transporting material to be taken out to the vacuum infinite far point” as used herein may be an ionization potential in the case of using an organic material, may be a work function in the case of using a metal, and may be the highest level of the valence electron band in the case of using an inorganic semiconductor. As examples of metals, there is illustrated any combination of members selected from among, for example, Li, Na, Mg, K, Ca, Rb, Sr, Cs, Ba, Fr, Ra, Sc, Ti, Y, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Al, Ga, In, Tl, Si, Ge, Sn, Pb, P, As, Sb, Bi, Se, Te, Po, Br, I, At, B, C, N, F, O, S and N.

Also, as preferred examples of the inorganic semiconductors, compound semiconductors represented by the group III-V semiconductors, the group II-VI semiconductors and metal chalcogenides or compounds having perovskite structure may be used as well as single semiconductors such as Si and Ge. Preferred examples of the metal chalcogenides include oxides of titanium, tin, zinc, iron, tungsten, zirconium, hafnium, strontium, indium, cerium, yttrium, lanthanum, vanadium, niobium and tantalum, sulfides of cadmium, zinc, lead, silver, antimony and bismuth, selenides of cadmium and lead and cadmium telluride. Examples of other compound semiconductors include phosphides of zinc, gallium, indium and cadmium, gallium arsenide, copper indium selenide and copper indium sulfide. Examples of oxide semiconductors include TiO₂, ZnO, SnO₂, Nb₂O₅, In₂O₃, WO₃, ZrO₂, La₂O₃, Ta₂O₅, SrTiO₃ and BaTiO₃. However, these are not limitative at all.

The hole transporting material in the invention is preferably an organic material or an inorganic semiconductor and, particularly preferably, the ionization potential of the electron transporting organic material is larger than the ionization potential of the hole transporting organic material. This energy difference is preferably 0.2 eV or more, more preferably 0.4 eV or more, still more preferably 0.6 eV or more. A hole transporting material having a small ionization potential is preferably used, because a small ionization potential of the hole transporting material permits the use of various electron transporting organic materials.

The electron transporting material for use in the present invention is preferably, for example, an organic semiconductor (compound) having an acceptor property. The organic semiconductor (compound) having an acceptor property is mainly represented by an electron transporting organic compound and indicates an organic compound having a property of readily accepting an electron, more specifically, an organic compound having a larger electron affinity when two organic compounds are used in contact with each other. Accordingly, any organic compound can be used as the organic compound having an acceptor property as long as it is an electron-accepting organic compound. Examples thereof include metal complexes having, as a ligand, a condensed aromatic carbocyclic compound (e.g., naphthalene derivative, anthracene derivative, phenanthrene derivative, tetracene derivative, pyrene derivative, perylene derivative, fluoranthene derivative), a 5-, 6- or 7-membered heterocyclic compound containing nitrogen atom, oxygen atom and sulfur atom (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyralidine, pyrrolopyridine, thiadiazolopyridine, dibenzazepine, tribenzazepine), a polyarylene compound, a fluorene compound, a cyclopentadiene compound, a silyl compound or a nitrogen-containing heterocyclic compound. However, the present invention is not limited to these compounds, and an organic compound exhibiting a larger electron affinity than the organic compound used for the organic compound having a donor property may be used as the organic semiconductor having an acceptor property.

In the case of using a definite hole transporting material, an electron transporting material having a larger ionization potential is more preferred to use therewith. There are not infinite compounds, which have a large ionization potential and are suited for the electron transporting material having a large ionization potential. In particular, there are extremely few compounds having an ionization potential of more than 6.0 eV. It is extremely difficult to find such compounds, but intensive investigation in the invention has lead to find them. One example thereof is a compound having the following structure of compound 119. Additionally, the ionization potential of the compound was measured by using AC-1 surface analyzer made by Riken Keiki K.K. Specifically, the amount of light was 20 to 50 nW, and analysis area was 4 mmφ.

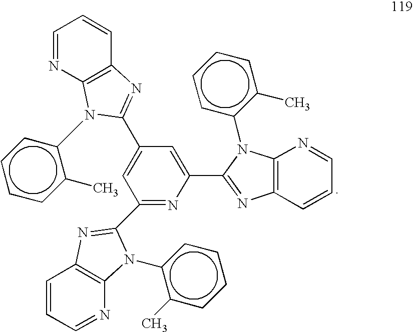

Further, surprisingly enough, a compound having a large ionization potential that can not be measured by means of AC-1 has been found. In such cases, the ionization potential can be measured by using, for example, UPS (Ultraviolet ray Photoelectric Spectroanalysis). It is the compound 21 to be described hereinafter that has been found. This is a big discovery.

Similarly with the above-mentioned compounds 119 and 21, there exist many compounds having a large ionization potential, and their characteristics are as follows. That is, in the invention, it is quite preferred to use compounds having the following structure as the electron transporting material.

First, description on the compounds represented by formula (I) is given. A represents a hetero ring group wherein two or more aromatic hetero rings are condensed, and plural hetero ring groups represented by A may be the same or different. The hetero ring group represented by A is preferably a group wherein 5- or 6-membered aromatic hetero rings are condensed with each other, more preferably a group wherein 2 to 6, still more preferably 2 to 3, particularly preferably 2, aromatic hetero rings are condensed with each other. Preferred examples of the hetero atom include N, O, S, Se and Te atoms, more preferred examples thereof include N, O and S atoms, yet more preferred example is a N atom. Specific examples of the aromatic hetero ring constituting the hetero ring group represented by A include furan, thiophene, pyran, pyrrole, imidazole, pyrazole, pyridine, pyrazine, pyrimidine, pyridazine, thiazole, oxazole, isothiazole, isoxazole, thiadiazole, oxadiazole, triazole, selenazole and tellurazole. More preferred examples thereof include imidazole, pyrazole, pyridine, pyrazine, pyrimidine, pyridazine, thiazole and oxazole, with imidazole, thiazole, oxazole, pyridine, pyrazine, pyrimidine and pyridazine being still more preferred.

Specific examples of the condensed ring represented by A include indolizine, purine, pteridine, carboline, pyrroloimidazole, pyrrolotriazole, pyrazoloimidazole, pyrazolotriazole, pyrazolopyrimidine, pyrazolotriazine, triazolopyridine, tetrazaindene, imidazoimidazole, imidazopyridine, imidazopyrazine, imidazopyrimidine, imidazopyridazine, oxazolopyridine, oxazolopyrazine, oxazolopyrimidine, oxazolopyridazine, thiazolopyridine, thiazolopyrazine, thiazolopyrimidine, thiazolopyridazine, pyridinopyrazine, pyrazinopyrazine, pyrazinopyridazine, naphthyridine and imidazotriazine. Preferred examples thereof include imidazopyridine, imidazopyrazine, imidazopyrimidine, imidazopyridazine, oxazolopyridine, oxazolopyrazine, oxazolopyrimidine, oxazolopyridazine, thiazolopyridine, thiazolopyrazine, thiazolopyrimidine, thiazolopyridazine, pyridinopyrazine and pyrazinopyrazine. More preferred examples thereof include imidazopyridine, oxazolopyridine, thiazolopyridine, pyridinopyrazine and pyrazinopyrazine, with imidazopyridine being particularly preferred.

The hetero ring group represented by A may further be condensed with other ring and may have a substituent. Examples of the substituent of the hetero ring group represented by A include an alkyl group (containing preferably 1 to 30 carbon atoms, more preferably 1 to 20 carbon atoms, particularly preferably 1 to 10 carbon atoms and being exemplified by methyl, ethyl, iso-propyl, tert-butyl, n-octyl, n-decyl, n-hexadecyl, cyclopropyl, cyclopentyl and cyclohexyl), an alkenyl group (containing preferably 2 to 30 carbon atoms, more preferably 2 to 20 carbon atoms, particularly preferably 2 to 10 carbon atoms and being exemplified by vinyl, allyl, 2-butenyl and 3-pentenyl), an alkynyl group (containing preferably 2 to 30 carbon atoms, more preferably 2 to 20 carbon atoms, particularly preferably 2 to 10 carbon atoms and being exemplified by propargyl and 3-pentynyl), an aryl group (containing preferably 6 to 30 carbon atoms, more preferably 6 to 20 carbon atoms, particularly preferably 6 to 12 carbon atoms and being exemplified by phenyl, p-methylphenyl and naphthyl), an amino group (containing preferably 0 to 30 carbon atoms, more preferably 0 to 20 carbon atoms, particularly preferably 0 to 10 carbon atoms and being exemplified by amino, methylamino, dimethylamino, diethylamino, dibenzylamino, diphenylamino and ditolylamino), an alkoxy group (containing preferably 1 to 30 carbon atoms, more preferably 1 to 20 carbon atoms, particularly preferably 1 to 10 carbon atoms and being exemplified by methoxy, ethoxy, butoxy and 2-ethylhexyloxy), an aryloxy group (containing preferably 6 to 30 carbon atoms, more preferably 6 to 20 carbon atoms, particularly preferably 6 to 12 carbon atoms and being exemplified by phenyloxy, 1-naphthyloxy and 2-naphthyloxy), an acyl group (containing preferably 1 to 30 carbon atoms, more preferably 1 to 20 carbon atoms, particularly preferably 2 to 12 carbon atoms and being exemplified by acetyl, benzoyl, formyl and pivaloyl), an alkoxycarbonyl group (containing preferably 2 to 30 carbon atoms, more preferably 2 to 20 carbon atoms, particularly preferably 2 to 12 carbon atoms and being exemplified by methoxycarbonyl and ethoxycarbonyl), an aryloxycarbonyl group (containing preferably 7 to 30 carbon atoms, more preferably 7 to 20 carbon atoms, particularly preferably 7 to 12 carbon atoms and being exemplified by phenyloxycarbonyl), an acyloxy group (containing preferably 2 to 30 carbon atoms, more preferably 2 to 20 carbon atoms, particularly preferably 2 to 10 carbon atoms and being exemplified by acetoxy and benzoyloxy), an acylamino group (containing preferably 2 to 30 carbon atoms, more preferably 2 to 20 carbon atoms, particularly preferably 2 to 10 carbon atoms and being exemplified by acetylamino and benzoylamino), an alkoxycarbonylamino group (containing preferably 2 to 30 carbon atoms, more preferably 2 to 20 carbon atoms, particularly preferably 2 to 12 carbon atoms and being exemplified by methoxycarbonylamino), an aryloxycarbonylamino group (containing preferably 7 to 30 carbon atoms, more preferably 7 to 20 carbon atoms, particularly preferably 7 to 12 carbon atoms and being exemplified by phenyloxycarbonylamino), a sulfonylamino group (containing preferably 1 to 30 carbon atoms, more preferably 1 to 20 carbon atoms, particularly preferably 1 to 12 carbon atoms and being exemplified by methanesulfonylamino and benzenesulfonylamino), a sulfamoyl group (containing preferably 0 to 30 carbon atoms, more preferably 0 to 20 carbon atoms, particularly preferably 0 to 12 carbon atoms and being exemplified by sulfamoyl, methylsulfamoyl, dimethylsulfamoyl and phenylsulfamoyl), a carbamoyl group (containing preferably 1 to 30 carbon atoms, more preferably 1 to 20 carbon atoms, particularly preferably 1 to 12 carbon atoms and being exemplified by carbamoyl, methylcarbamoyl, diethylcarbamoyl and phenylcarbamoyl), an alkylthio group (containing preferably 1 to 30 carbon atoms, more preferably 1 to 20 carbon atoms, particularly preferably 1 to 12 carbon atoms and being exemplified by methylthio and ethylthio), an arylthio group (containing preferably 6 to 30 carbon atoms, more preferably 6 to 20 carbon atoms, particularly preferably 6 to 12 carbon atoms and being exemplified by phenylthio), a sulfonyl group (containing preferably 1 to 30 carbon atoms, more preferably 1 to 20 carbon atoms, particularly preferably 1 to 12 carbon atoms and being exemplified by mesyl and tosyl), a sulfinyl group (containing preferably 1 to 30 carbon atoms, more preferably 1 to 20 carbon atoms, particularly preferably 1 to 12 carbon atoms and being exemplified by methanesulfinyl and benzenesulfinyl), a ureido group (containing preferably 1 to 30 carbon atoms, more preferably 1 to 20 carbon atoms, particularly preferably 1 to 12 carbon atoms and being exemplified by ureido, methylureido and phenylureido), a phosphoric acid amido group (containing preferably 1 to 30 carbon atoms, more preferably 1 to 20 carbon atoms, particularly preferably 1 to 12 carbon atoms and being exemplified by diethylphosphamido and phenylphosphamido), a hydroxyl group, a mercapto group, a halogen atom (e.g., fluorine atom, chlorine atom, bromine atom or iodine atom), a cyano group, a sulfo group, a carboxyl group, a nitro group, a hydroxamic acid group, a sulfino group, a hydrazine group, an imino group, a hetero ring group (containing preferably 1 to 30 carbon atoms, more preferably 1 to 12 carbon atoms and containing, for example, a nitrogen atom, an oxygen atom or a sulfur atom as a hetero atom; specific examples thereof including imidazolyl, pyridyl, quinolyl, furyl, thienyl, piperidyl, morpholino, benzoxazolyl, benzimidazolyl, benzothiazolyl, carbazolyl and azepinyl), and a silyl group (containing preferably 3 to 40 carbon atoms, more preferably 3 to 30 carbon atoms, particularly preferably 3 to 24 carbon atoms and being exemplified by trimethylsilyl and triphenylsilyl). These substituents may further be substituted. Also, in the case when they have two or more substituents, the substituents may be the same or different and, if possible, may be connected to each other to form a ring.

Preferred examples of the substituent for the hetero ring group represented by A include an alkyl group, an alkenyl group, an alkynyl group, an aryl group, an amino group, an alkoxy group, an aryloxy group, an acyl group, an alkoxycarbonyl group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, a sulfonyl group, a halogen atom, a cyano group and a hetero ring group. More preferred examples thereof include an alkyl group, an alkenyl group, an aryl group, an alkoxy group, an aryloxy group, a halogen atom, a cyano group and a hetero ring group. More preferred examples thereof include an alkyl group, an aryl group, an alkoxy group, an aryloxy group and an aromatic hetero ring group, with an alkyl group, an aryl group, an alkoxy group and an aromatic hetero ring group being particularly preferred. m represents an integer of 2 or more, preferably 2 to 8, more preferably 2 to 6, still more preferably 2 to 4, particularly preferably 2 or 3, most preferably 3. L represents a linking group. The linking group represented by L is preferably a single bond or a linking group formed by C, N, O, S, Si and Ge, more preferably a single bond, alkylene, alkenylene, alkynylene, arylene, divalent hetero ring (preferably aromatic hetero ring, more preferably aromatic hetero ring formed by azole, thiophene or furan ring) and a group comprising N and a combination thereof, still more preferably arylene, divalent aromatic hetero ring and a group comprising N and a combination thereof.

Specific examples of the linking group represented by L include the following ones as well as a single bond.

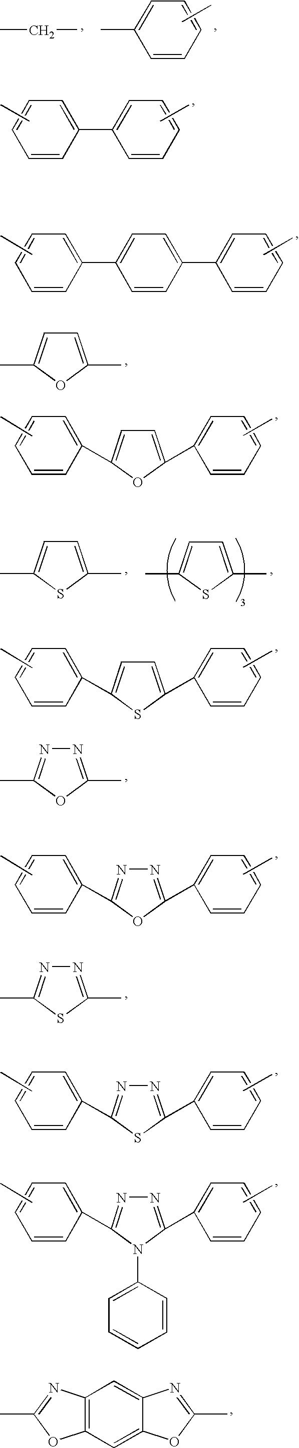

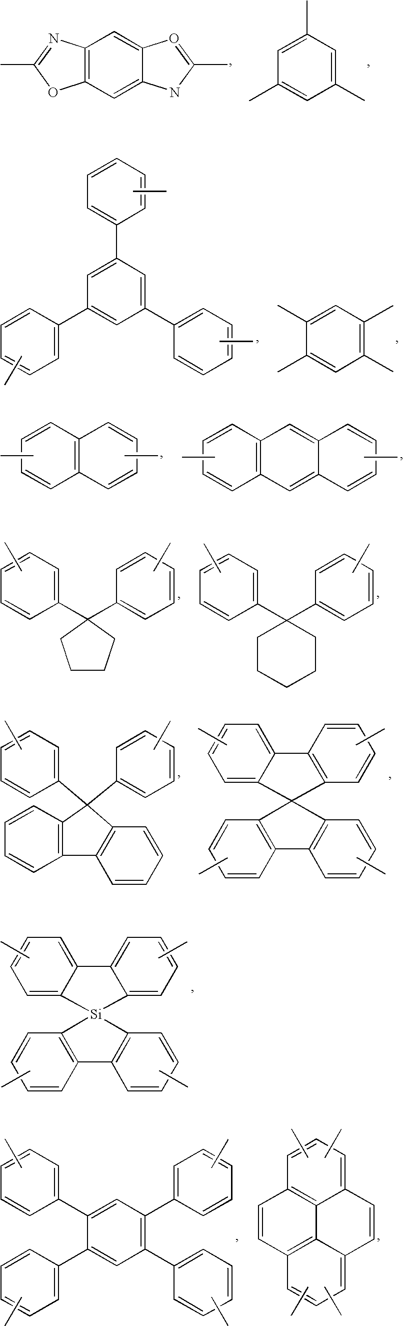

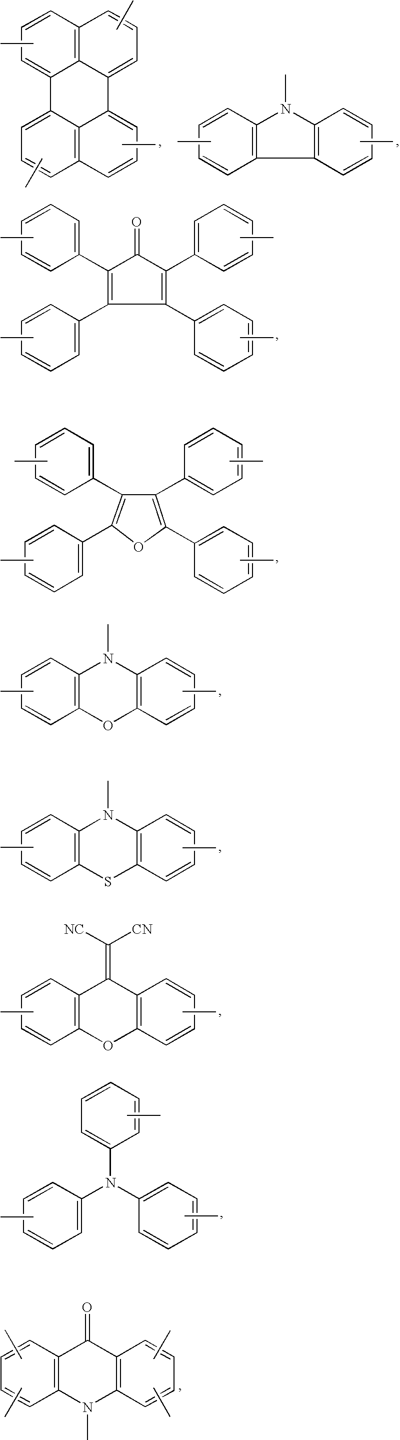

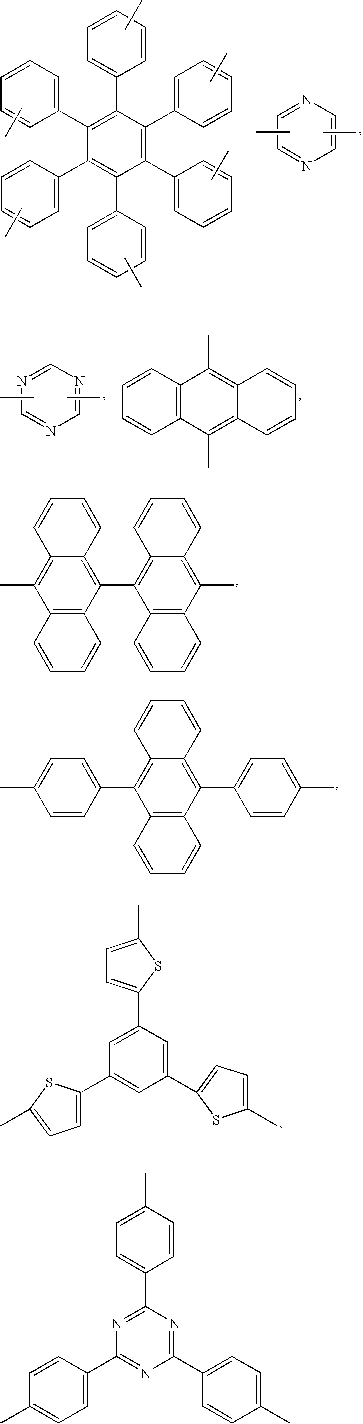

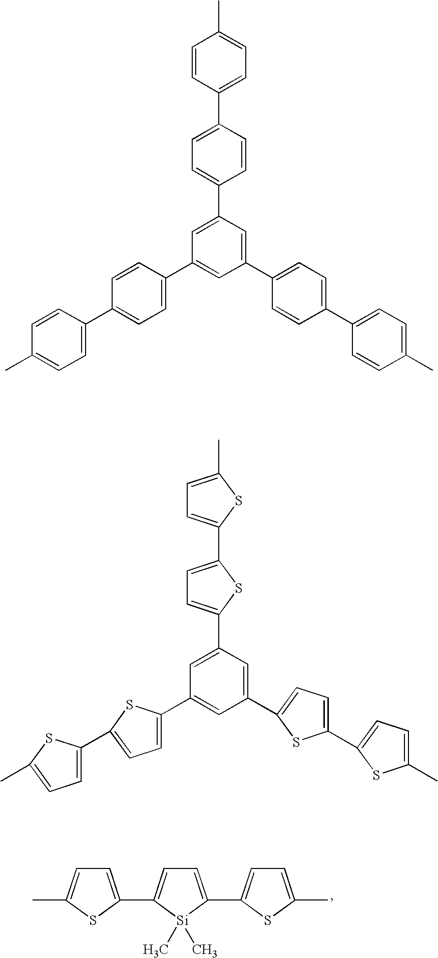

The linking group represented by L may have a substituent and, as such substituent, those which have been illustrated as substituents for the hetero ring group represented by A may be employed. Preferred examples of the substituent for L include an alkyl group, an alkenyl group, an alkynyl group, an aryl group, an alkoxy group, an aryloxy group, an acyl group, a halogen atom, a cyano group, a hetero ring group and a silyl group. More preferred examples thereof include an alkyl group, an alkenyl group, an alkynyl group, an aryl group, an alkoxy group, an aryloxy group, a halogen atom, a cyano group and an aromatic hetero ring group, with an alkyl group, an aryl group and an aromatic hetero ring group being still more preferred.

Of the compounds represented by formula (I), those compounds that are represented by the following formula (II) are preferred.

LB)ₘ Formula (II)

wherein m and L are the same as defined with respect to those in formula (I), with preferred scopes thereof being also the same. Each of B's independently represents a hetero ring group where two or more 5- and/or 6-membered aromatic hetero rings are condensed with each other, and the hetero ring groups represented by B's may be the same or different. The hetero ring group represented by B is a hetero ring group wherein preferably 2 to 6, more preferably 2 or 3, particularly preferably 2,5- or 6-membered aromatic hetero rings are condensed with each other. Examples of the hetero atom in the hetero ring group include N, O, S, Se and Te atoms. More preferred examples thereof include N, O and S atoms, with N atom being still more preferred. Specific examples of the aromatic hetero ring constituting the hetero ring group represented by B include furan, thiophene, pyran, pyrrole, imidazole, pyrazole, pyridine, pyrazine, pyrimidine, pyridazine, thiazole, oxazole, isothiazole, isoxazole, thiadiazole, oxadiazole, triazole, selenazole and tellurazole. Preferred examples thereof include imidazole, pyrazole, pyridine, pyrazine, pyrimidine, pyridazine, thiazole and oxazole, with imidazole, thiazole, oxazole, pyridine, pyrazine, pyrimidine and pyridazine being more preferred.

Specific examples of the condensed ring represented by B include indolizine, purine, pteridine, carboline, pyrroloimidazole, pyrrolotriazole, pyrazoloimidazole, pyrazolotriazole, pyrazolopyrimidine, pyrazolotriazine, triazolopyridine, tetrazaindene, pyrroloimidazole, pyrrolotriazole, imidazoimidazole, imidazopyridine, imidazopyrazine, imidazopyrimidine, imidazopyridazine, oxazolopyridine, oxazolopyrazine, oxazolopyrimidine, oxazolopyridazine, thiazolopyridine, thiazolopyrazine, thiazolopyrimidine, thiazolopyridazine, pyridinopyrazine, pyrazinopyrazine, pyrazinopyridazine, naphthyridine and imidazotriazine. Preferred examples thereof include imidazopyridine, imidazopyrazine, imidazopyrimidine, imidazopyridazine, oxazolopyridine, oxazolopyrazine, oxazolopyrimidine, oxazolopyridazine, thiazolopyridine, thiazolopyrazine, thiazolopyrimidine, thiazolopyridazine, pyridinopyrazine and pyrazinopyrazine. More preferred examples thereof include imidazopyridine, oxazolopyridine, thiazolopyridine, pyridinopyrazine and pyrazinopyrazine, with imidazopyridine being particularly preferred. The hetero ring group represented by B may have a substituent and, as the substituent, those which have been illustrated as substituents for the hetero ring group represented by A in formula (I) may be employed, with preferred substituents being also the same.

Of the compounds represented by formula (I), those compounds that are represented by the following formula (III) or (XI) are more preferred.

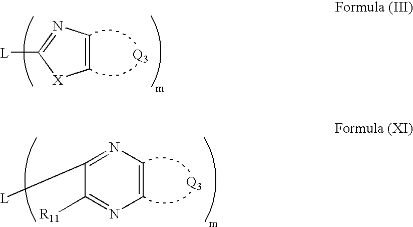

Descriptions on formula (III) are given below. m and L are the same as defined with respect to those in formula (I), with preferred scopes thereof being also the same as described there. Each of X's independently represents O, S, Se, Te or N—R. R represents a hydrogen atom, an aliphatic hydrocarbon group, an aryl group or a hetero ring group. Each of Q₃'s independently represents an atomic group necessary for forming an aromatic hetero ring. Preferred examples of the aliphatic hydrocarbon group represented by R include an alkyl group (containing preferably 1 to 20 carbon atoms, more preferably 1 to 12 carbon atoms, particularly preferably 1 to 8 carbon atoms and being exemplified by methyl, ethyl, iso-propyl, tert-butyl, n-octyl, n-decyl, n-hexadecyl, cyclopropyl, cyclopentyl and cyclohexyl), an alkenyl group (containing preferably 2 to 20 carbon atoms, more preferably 2 to 12 carbon atoms, particularly preferably 2 to 8 carbon atoms and being exemplified by vinyl, allyl, 2-butenyl and 3-pentenyl) and an alkynyl group (containing preferably 2 to 20 carbon atoms, more preferably 2 to 12 carbon atoms, particularly preferably 2 to 8 carbon atoms and being exemplified by propargyl and 3-pentynyl), with an alkyl group and an alkenyl group being preferred.

The aryl group represented by R contains preferably 6 to 30 carbon atoms, more preferably 6 to 20 carbon atoms, particularly preferably 6 to 12 carbon atoms, and examples thereof include phenyl, 2-methylphenyl, 3-methylphenyl, 4-methylphenyl, 4-methoxyphenyl, 3-trifluoromethylphenyl, pentafluorophenyl, 2-biphenylyl, 3-biphenylyl, 4-biphenylyl, 1-naphthyl, 2-naphthyl and 1-pyrenyl. The hetero ring group represented by R is a monocyclic or condensed hetero ring group (containing preferably 1 to 20 carbon atoms, more preferably 1 to 12 carbon atoms, still more preferably 2 to 10 carbon atoms) and is an aromatic hetero ring group preferably containing at least one of a nitrogen atom, an oxygen atom, a sulfur atom and a selenium atom. Specific examples of the hetero ring group represented by R include pyrrolidine, piperidine, pyrrole, furan, thiophene, imidazoline, imidazole, benzimidazole, naphthimidazole, thiazolidine, thiazole, benzothiazole, naphthothiazole, isothiazole, oxazoline, oxazole, benzoxazole, naphthoxazole, isoxazole, selenazole, benzoselenazole, naphthoselenazole, pyridine, quinoline, isoquinoline, indole, indolenine, pyrazole, pyrazine, pyrimidine, pyridazine, triazine, indazole, purine, phthalazine, naphthyridine, quinoxaline, quinazoline, cinnoline, pteridine, phenanthridine, pteridine, phenanthroline and tetrazaindene. Preferred examples thereof include furan, thiophene, pyridine, quinoline, pyrazine, pyrimidine, pyridazine, triazine, phthalazine, naphthyridine, quinoxaline and quinazoline. More preferred examples thereof include furan, thiophene, pyridine and quinoline, with quinoline being particularly preferred.

The aliphatic hydrocarbon group, aryl group and hetero ring group represented by R may have a substituent and, as the substituent, those which have been illustrated as substituents for the hetero ring group represented by A in formula (I) may be employed, with the preferred scope thereof being also the same as described there. Preferred examples of R include an alkyl group, an aryl group and an aromatic hetero ring group, more preferred examples thereof include an aryl group and an aromatic hetero ring group, and still more preferred examples thereof include an aryl group and an aromatic azole group.

Preferred examples of X include O, S and N—R, more preferred examples thereof include O and N—R, and more preferred examples thereof include N—R, and particularly preferred examples thereof include N—Ar (wherein Ar represents an aryl group or an aromatic azole group, more preferably an aryl group containing 6 to 30 carbon atoms or an aromatic azole group containing 2 to 30 carbon atoms, still more preferably an aryl group containing 6 to 20 carbon atoms or an aromatic azole group containing 2 to 16 carbon atoms, and particularly preferably an aryl group containing 6 to 12 carbon atoms or an aromatic azole group containing 2 to 10 carbon atoms).

Q₃ represents an atomic group necessary for forming an aromatic hetero ring. The aromatic hetero ring formed by Q₃ is preferably a 5- or 6-membered aromatic hetero ring, more preferably a 5- or 6-membered, nitrogen-containing aromatic hetero ring, still more preferably a 5- or 6-membered, nitrogen-containing aromatic hetero ring. Specific examples of the aromatic hetero ring formed by Q₃ include furan, thiophene, pyran, pyrrole, imidazole, pyrazole, pyridine, pyrazine, pyrimidine, pyridazine, thiazole, oxazole, isothiazole, isoxazole, thiadiazole, oxadiazole, triazole, selenazole and tellurazole. Preferred examples thereof include pyridine, pyrazine, pyrimidine and pyridazine. More preferred examples thereof include pyridine and pyrazine, with pyridine being still more preferred. The aromatic hetero ring formed by Q₃ may be further condensed with other ring to form a condensed ring and may have a substituent. As the substituent, those which have been illustrated as substituents for the hetero ring group represented by A in formula (I) may be employed, and preferred examples thereof are also the same as described there.

Of the compounds represented by formula (III), those compounds that are represented by the following formula (IV) are more preferred.

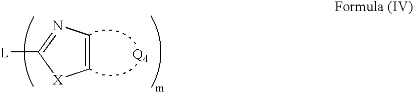

In formula (IV), m and L are the same as defined with respect to those in formula (I), with preferred scopes thereof being also the same as described there. X is the same as defined in formula (III), with preferred scope thereof being also the same as described there. Each of Q₄'s independently represents an atomic group necessary for forming a nitrogen-containing, aromatic hetero ring. The nitrogen-containing, aromatic hetero ring group represented by Q₄ is preferably a 5- or 6-membered, nitrogen-containing aromatic hetero ring, more preferably a 6-membered, nitrogen containing aromatic hetero ring. Specific examples of the nitrogen-containing aromatic hetero ring formed by Q₄ include pyrrole, imidazole, pyrazole, pyridine, pyrazine, pyrimidine, pyridazine, thiazole, oxazole, isothiazole, isoxazole, thiadiazole, oxadiazole, triazole, selenazole and tellurazole. Preferred examples thereof include pyridine, pyrazine, pyrimidine and pyridazine. More preferred examples thereof are pyridine and pyrazine, with pyridine being still more preferred. The aromatic hetero ring formed by Q₄ may form a condensed ring together with other ring or may have a substituent. As the substituent, those which have been illustrated as substituents for the hetero ring group represented by A in formula (I) may be employed, and preferred substituents are also the same as described there.

Of the compounds represented by formula (III), those that are represented by the following formula (V) are more preferred.

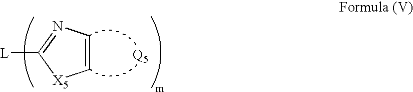

In formula (V), m and L are the same as defined with respect to those in formula (I), with preferred scopes thereof being also the same as described there. Each of X₅'s independently represents O, S or N—R. R is the same as defined in formula (III), with preferred scope thereof being also the same as described there. Each of Q₅'s independently represents an atomic group necessary for forming a 6-membered, nitrogen-containing aromatic hetero ring. Specific examples of the 6-membered, nitrogen-containing aromatic hetero ring formed by Q₅ include pyridine, pyrazine, pyrimidine, pyridazine and triazine. Preferred examples thereof include pyridine, pyrazine, pyrimidine and pyridazine. More preferred examples thereof are pyridine and pyrazine, with pyridine being still more preferred. The aromatic hetero ring formed by Q₅ may form a condensed ring together with other ring or may have a substituent. As the substituent, those which have been illustrated as substituents for the hetero ring group represented by A in formula (I) may be employed, and preferred substituents are also the same as described there.

Of the compounds represented by formula (III), those that are represented by the following formula (VI) are still more preferred.

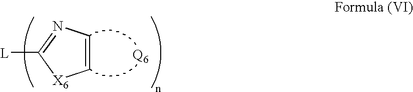

In formula (VI), L is the same as defined with respect to that in formula (I), with preferred scopes thereof being also the same as described there. X₆ is the same as X₅ defined with respect to formula (V), with preferred scope thereof being also the same as described there. Q₆ is the same as Q₅ defined with respect to formula (V), with preferred scope thereof being also the same as described there. n represents an integer of 2 to 8, preferably 2 to 6, more preferably 2 to 4, still more preferably 2 or 3, particularly preferably 3. Of the compounds represented by formula (III), those compounds that are represented by the following formula (VII) are yet more preferred.

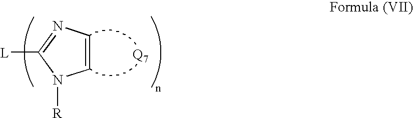

In formula (VII), L is the same as defined with respect to that in formula (I), with preferred scopes thereof being also the same as described there. Q₇ is the same as Q₅ defined with respect to formula (V), with preferred scope thereof being also the same as described there. n is the same as that defined in formula (VI), with preferred scopes thereof being also the same as described there.

Of the compounds represented by formula (III), those compounds that are represented by the following formula (VIII) are yet more preferred.

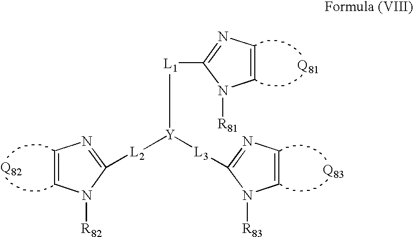

In formula (VIII), R₈₁, R₈₂ and R₈₃ are the same as R defined in formula (III), and the preferred scopes thereof are also the same as described there. Q₈₁, Q₈₂ and Q₈₃ are the same as Q₅ defined in formula (V), and the preferred scopes thereof are also the same as described there. L₁, L₂ and L₃ are the same as L defined in formula (I). L₁, L₂ and L₃ each preferably independently represents a single bond, an arylene group, a divalent aromatic hetero ring or a linking group comprising a combination thereof, more preferably represents a single bond, benzene, naphthalene, anthracene, pyridine, pyrazine, thiophene, furan, oxazole, thiazole, oxadiazole, thiadiazole, triazole or a linking group comprising a combination thereof, still more preferably represents a single bond, benzene, thiophene or a linking group comprising a combination thereof, particularly preferably a single bond, benzene or a linking group comprising a combination thereof, most preferably a single bond. L₁, L₂ and L₃ may have a substituent and, as such substituent, those substituents which have been illustrated as substituents for the hetero ring group represented by A in formula (I) may be employed.

Y represents a nitrogen atom or an 1,3,5-benzenetriyl group, which may have substituents such as an alkyl group, an aryl group or a halogen atom on 2,4,6 position thereof. Y preferably represents a nitrogen atom or an unsubstituted 1,3,5-benzenetriyl group, more preferably an unsubstituted 1,3,5-benzenetriyl group. Of the compounds represented by formula (III), those compounds that are represented by the following formula (IX) are particularly preferred.

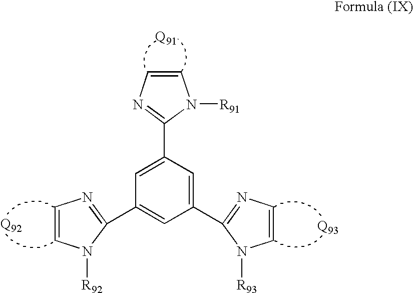

In formula (IX), R₉₁, R₉₂ and R₉₃ are the same as R defined in formula (III), and the preferred scopes thereof are also the same as described there. Q₉₁, Q₉₂ and Q₉₃ are the same as Q₅ defined in formula (V), and the preferred scopes thereof are also the same as described there. Of the compounds represented by the formula (III), those compounds that are represented by the following formula (X) are most preferred.

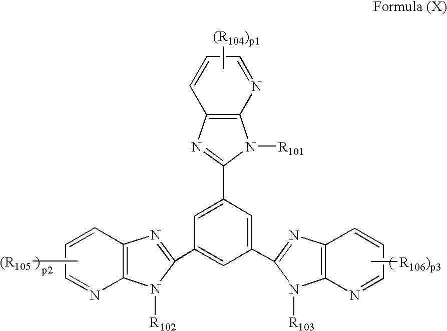

In formula (X), R₁₀₁, R₁₀₂ and R₁₀₃ are the same as R defined in formula (III). R₁₀₄, R₁₀₅ and R₁₀₆ each independently represents a substituent and, as such substituents, those which have been illustrated as substituents for the hetero ring group represented by A in formula (I) may be employed, with preferred substituents being also the same as described there. If possible, the substituents may be connected to each other to form a ring. p1, p2 and p3 each independently represents an integer of 0 to 3, preferably 0 to 2, more preferably 0 or 1, still more preferably 0. When p1, p2 and p3 are 2 or more, R₁₀₄'s, R₁₀₅'s and R₁₀₆'s may be the same or different, respectively.

Next, descriptions on formula (XI) are given below. m and L are the same as those in formula (I), and preferred scopes thereof are also the same as described there. Q₃ is the same as that in formula (III), and a preferred scope thereof is also the same as described there. R₁₁ represents a hydrogen atom or a substituent. As the substituent represented by R₁₁, there may be employed, for example, those which have been illustrated as substituents for the hetero ring group represented by A in formula (I). The substituent represented by R₁₁ is preferably an aliphatic hydrocarbon group, an aryl group or an aromatic hetero ring group, more preferably an alkyl group (containing preferably 1 to 20 carbon atoms, more preferably 1 to 12 carbon atoms, particularly preferably 1 to 8 carbon atoms and being exemplified by methyl, ethyl, iso-propyl, tert-butyl, n-octyl, n-decyl, n-hexadecyl, cyclopropyl, cyclopentyl and cyclohexyl), an aryl group (containing preferably 6 to 30 carbon atoms, more preferably 6 to 20 carbon atoms, particularly preferably 6 to 12 carbon atoms and being exemplified by phenyl, 2-methylphenyl, 3-methylphenyl, 4-methylphenyl, 4-methoxyphenyl, 3-trifluoromethylphenyl, pentafluorophenyl, 1-naphthyl and 2-naphthyl), an aromatic hetero ring group (preferably aromatic hetero ring group containing 1 to 20 carbon atoms, preferably 1 to 12 carbon atoms, still more preferably 2 to 10 carbon atoms and, more preferably aromatic hetero ring group containing at least one of nitrogen atom, oxygen atom, sulfur atom and selenium atom; examples of aromatic hetero ring being pyrrolidine, piperidine, pyrrole, furan, thiophene, imidazoline, imidazole, benzimidazole, naphthimidazole, thiazoline, thiazole, benzothiazole, naphthothiazole, isothiazole, oxazoline, oxazole, benzoxazole, naphthoxazole, isoxazole, selenazole, benzoselenazole, naphthoselenazole, pyridine, quinoline, isoquinoline, indole, indolenine, pyrazole, pyrazine, pyrimidine, pyridazine, triazine, indazole, purine, phthalazine, naphthyridine, quinoxaline, quinazoline, cinnoline, pteridine, phenanthroline, tetrazaindene and carbazole, preferably furan, thiophene, pyridine, quinoline, pyrazine, pyrimidine, pyridazine, triazine, phthalazine, naphthyridine, quinoxaline and quinazoline, more preferably furan, thiophene, pyridine and quinoline, still more preferably quinoline), still more preferably an aryl group or an aromatic hetero ring group. The substituent represented by R₁₁ may further be substituted or, if possible, may be connected to form a ring.

Of the compounds represented by formula (XI), those compounds that are represented by the following formula (XII) are more preferred.

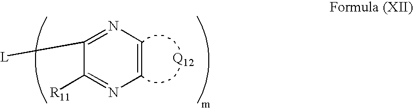

In the formula (XII), m and L are the same as those in formula (I), and preferred scopes thereof are also the same as described there. Q₁₂ is the same as Q₄ defined with respect to formula (IV), and preferred scope thereof is also the same as described there. R₁₁ is the same as those in formula (XI), and preferred scope thereof is also the same as described there.

Of the compounds represented by formula (XI), those compounds that are represented by the following formula (XIII) are still more preferred.

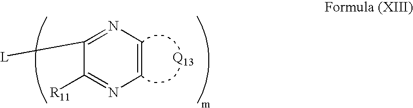

In the formula (XIII), m and L are the same as those in formula (I), and preferred scopes thereof are also the same as described there. Q₁₃ is the same as Q₅ defined with respect to formula (V), and preferred scope thereof is also the same as described there. R₁₁ is the same as that in formula (XI), and preferred scopes thereof are also the same as described there.

Of the compounds represented by formula (XI), those compounds that are represented by the following formula (XIV) are particularly preferred.

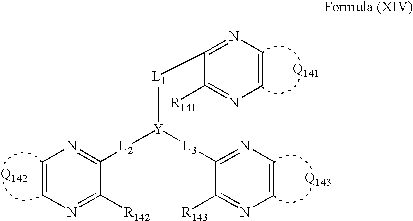

In the formula (XIV), L₁, L₂, L₃ and Y are the same as those defined with respect to formula (VIII), and preferred scopes thereof are also the same as described there. Q₁₄₁, Q₁₄₂ and Q₁₄₃ are the same as Q₅ defined with respect to formula (V), and preferred scopes thereof are also the same as described there. R₁₄₁, R₁₄₂ and R₁₄₃ are the same as R₁₁ defined with respect to formula (XI), and preferred scopes thereof are also the same as described there.

Of the compounds represented by formula (XI), those compounds that are represented by the following formula (XV) are most preferred.

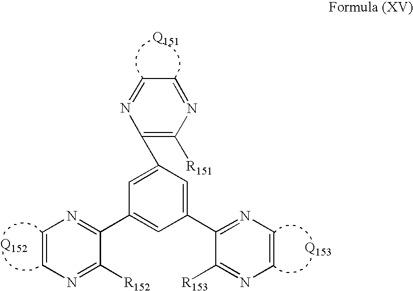

In the formula (XV), Q₁₅₁, Q₁₅₂ and Q₁₅₃ are the same as Q₅ defined with respect to formula (V), and preferred scopes thereof are also the same as described there. R₁₅₁, R₁₅₂ and R₁₅₃ are the same as R₁₁ defined with respect to formula (XI), and preferred scopes thereof are also the same as described there.

Specific examples of the compound of the invention represented by formula (I) are shown below which, however, do not limit the invention in any way.

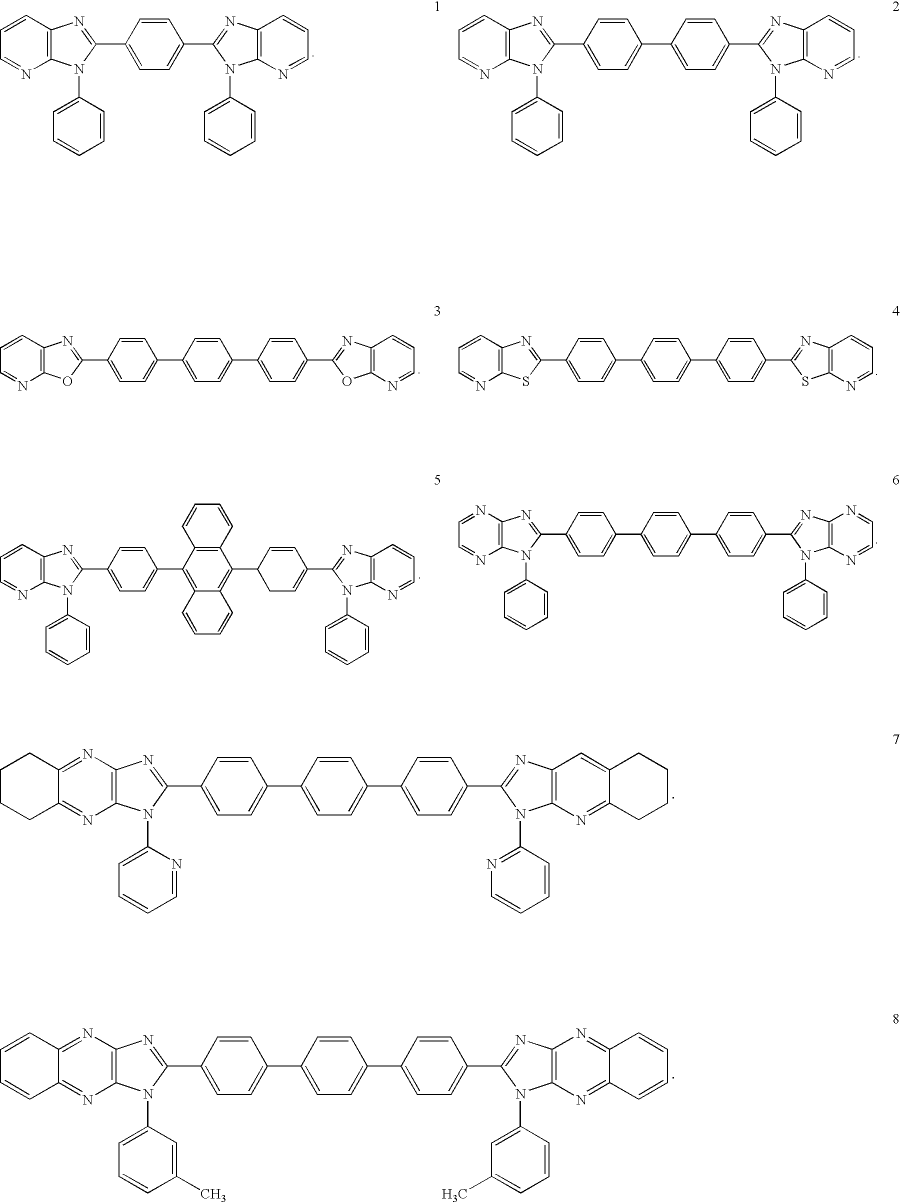

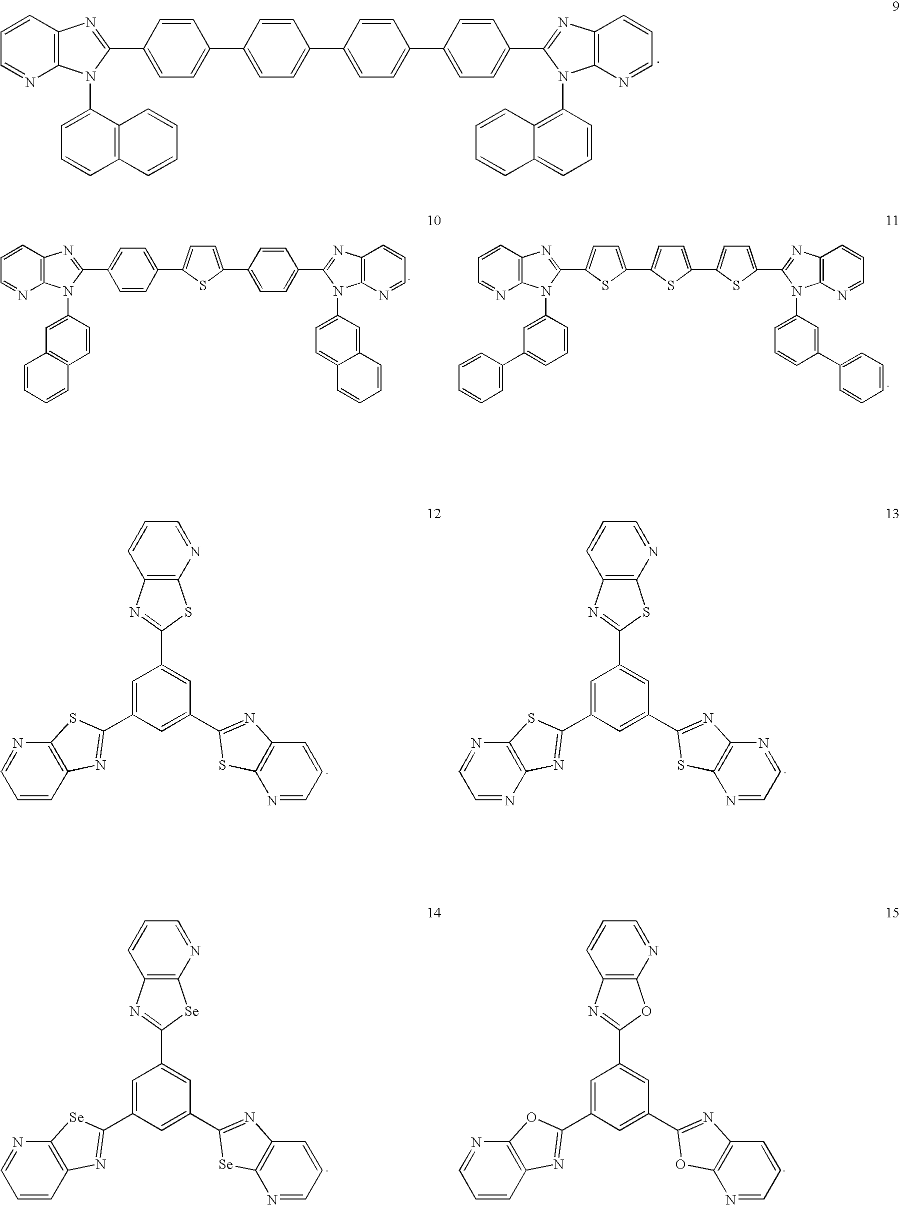

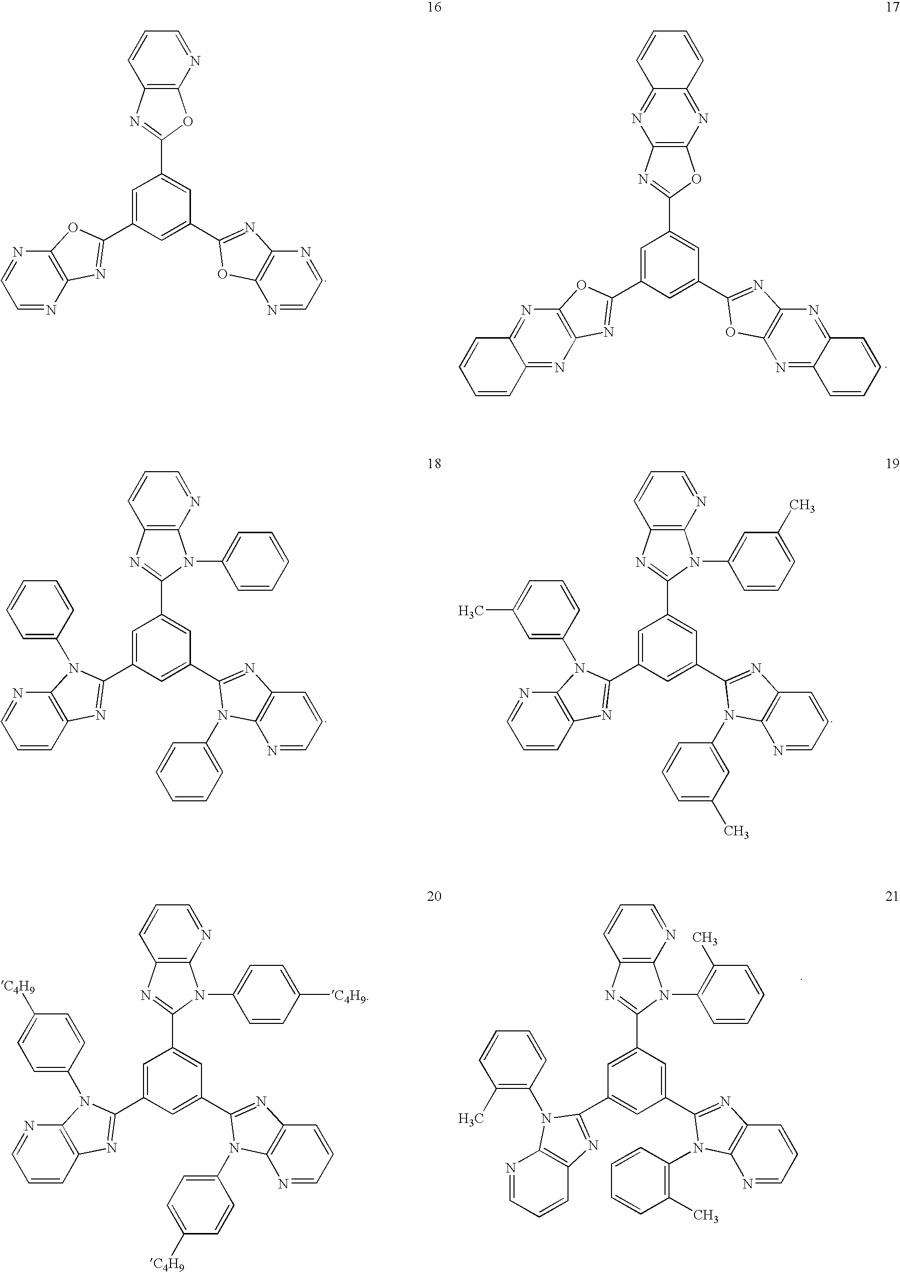

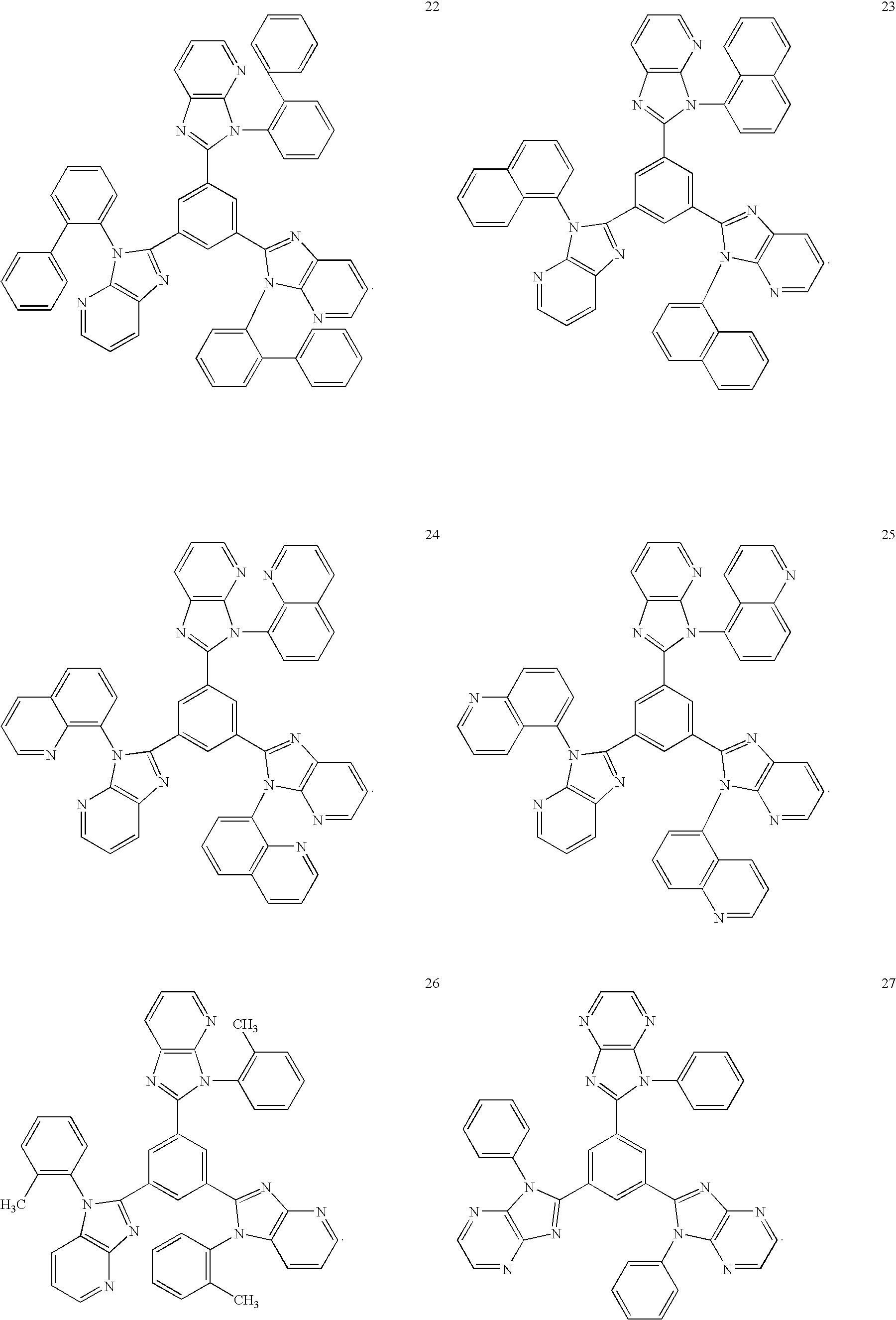

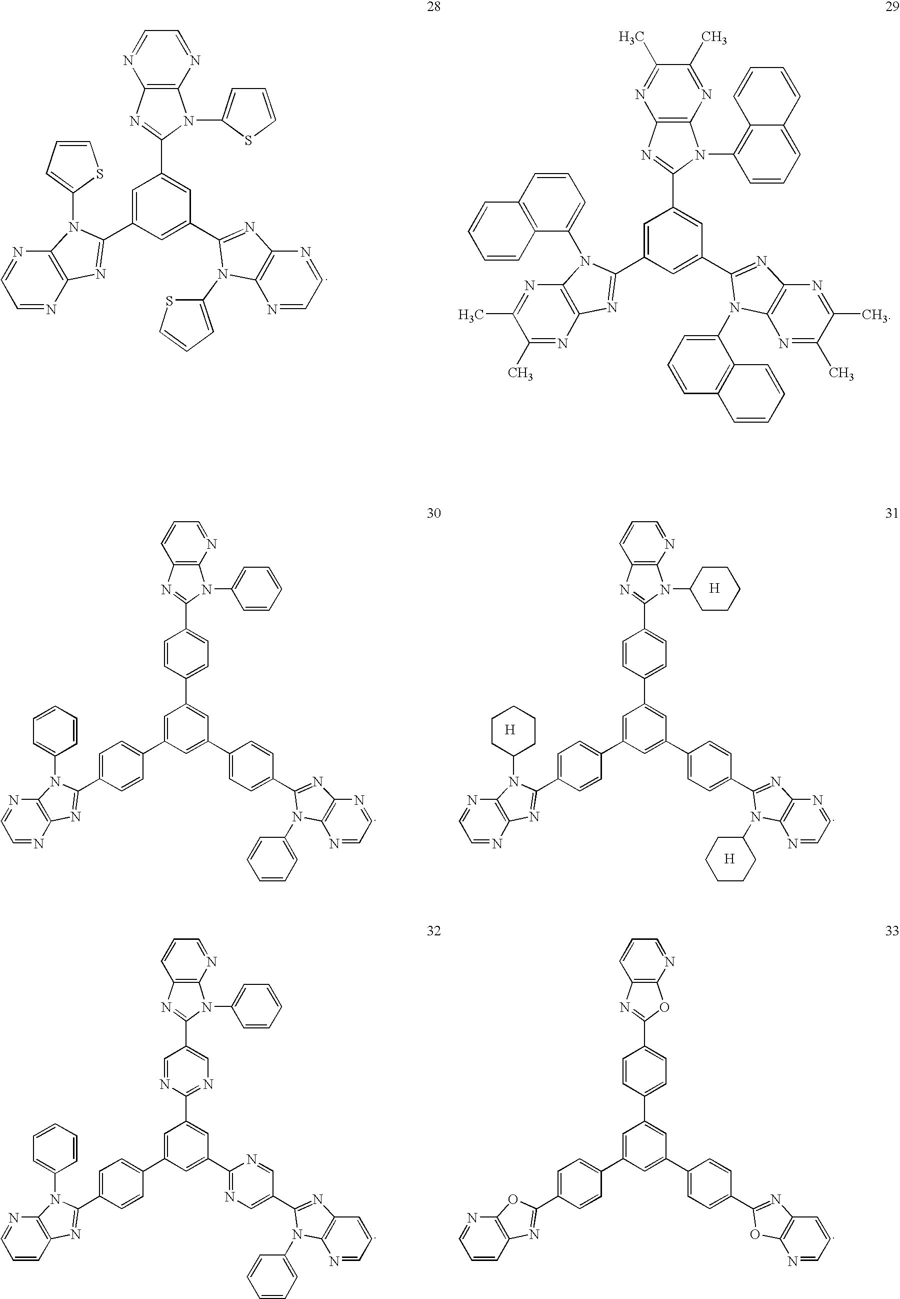

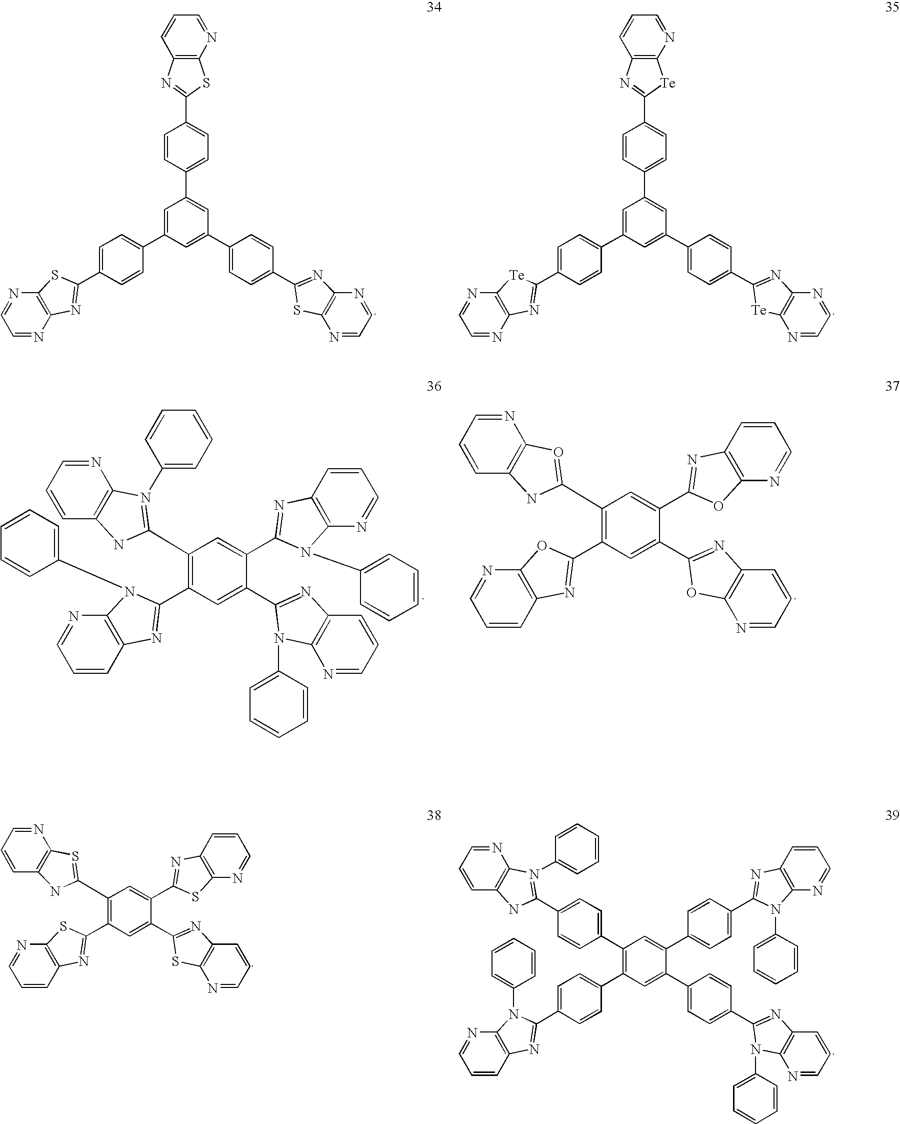

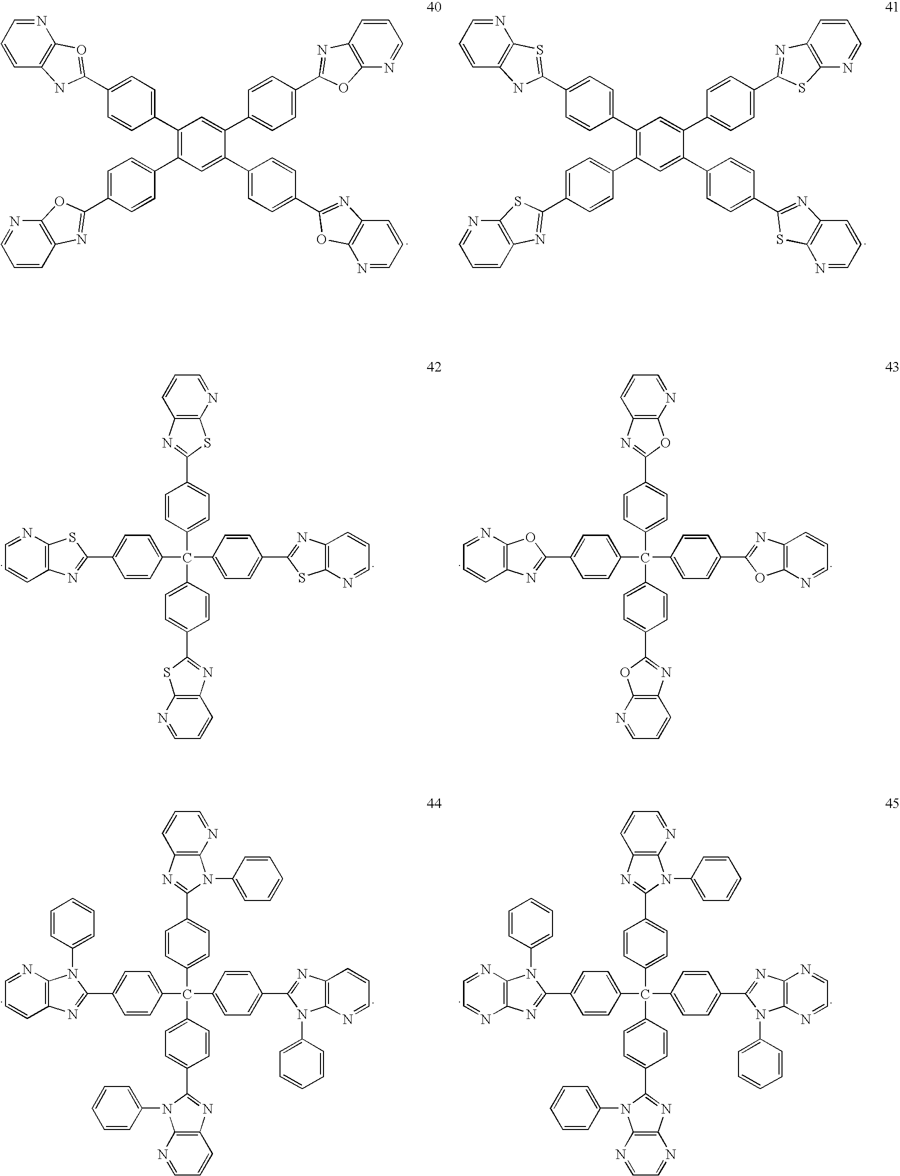

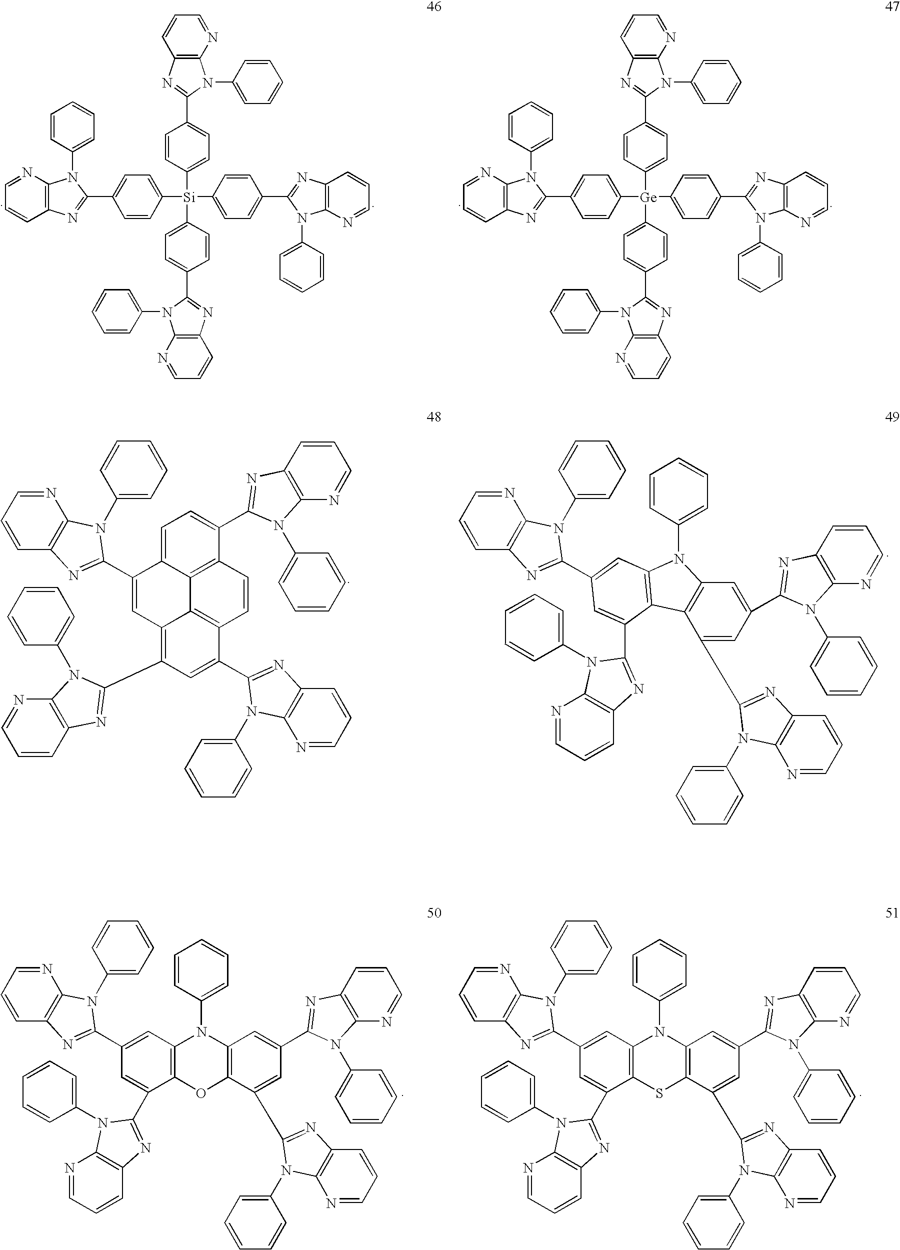

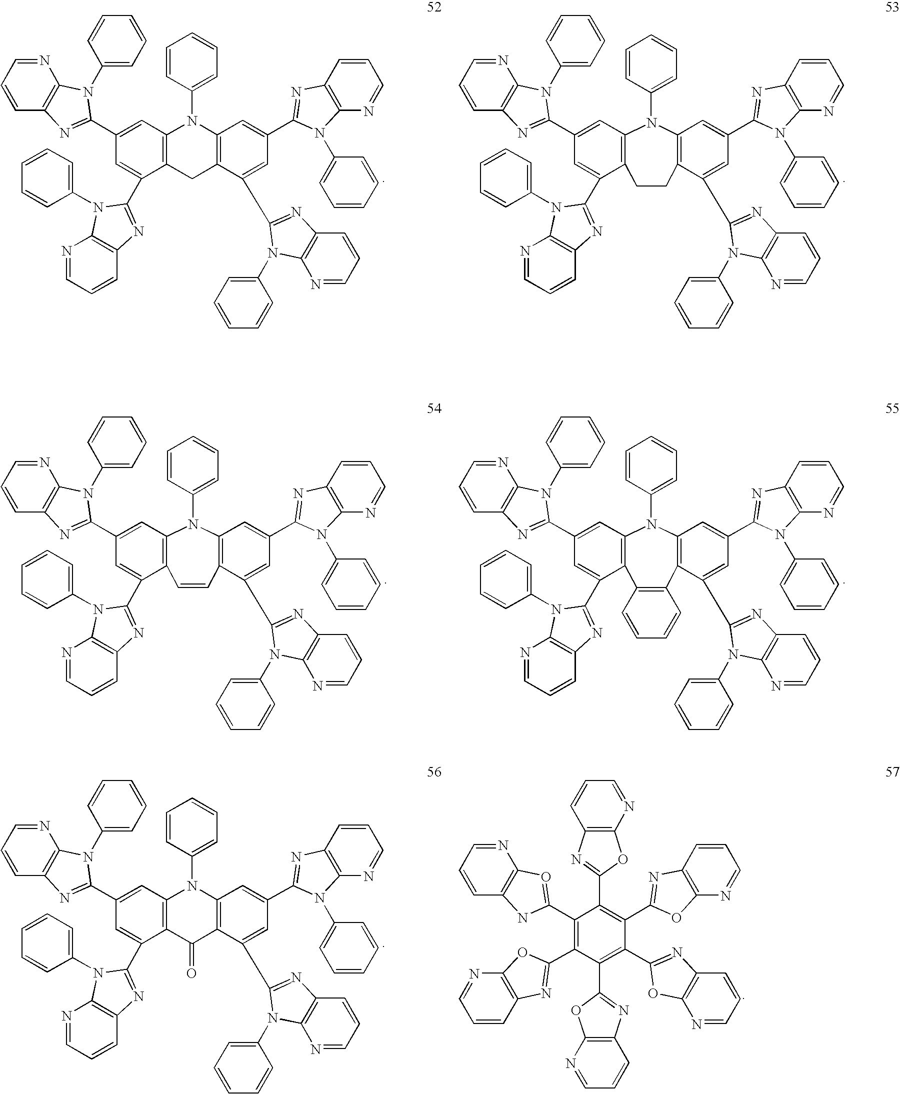

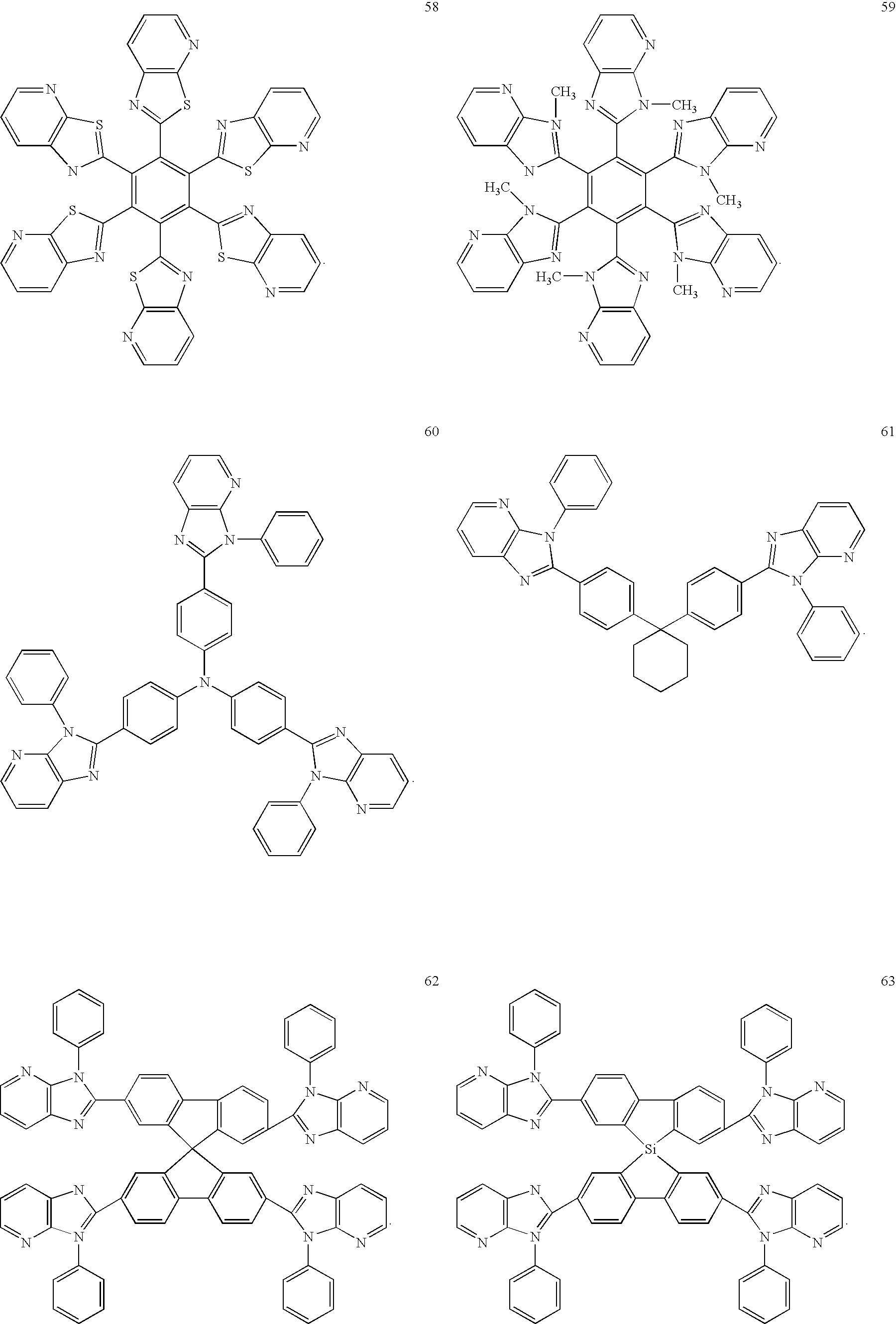

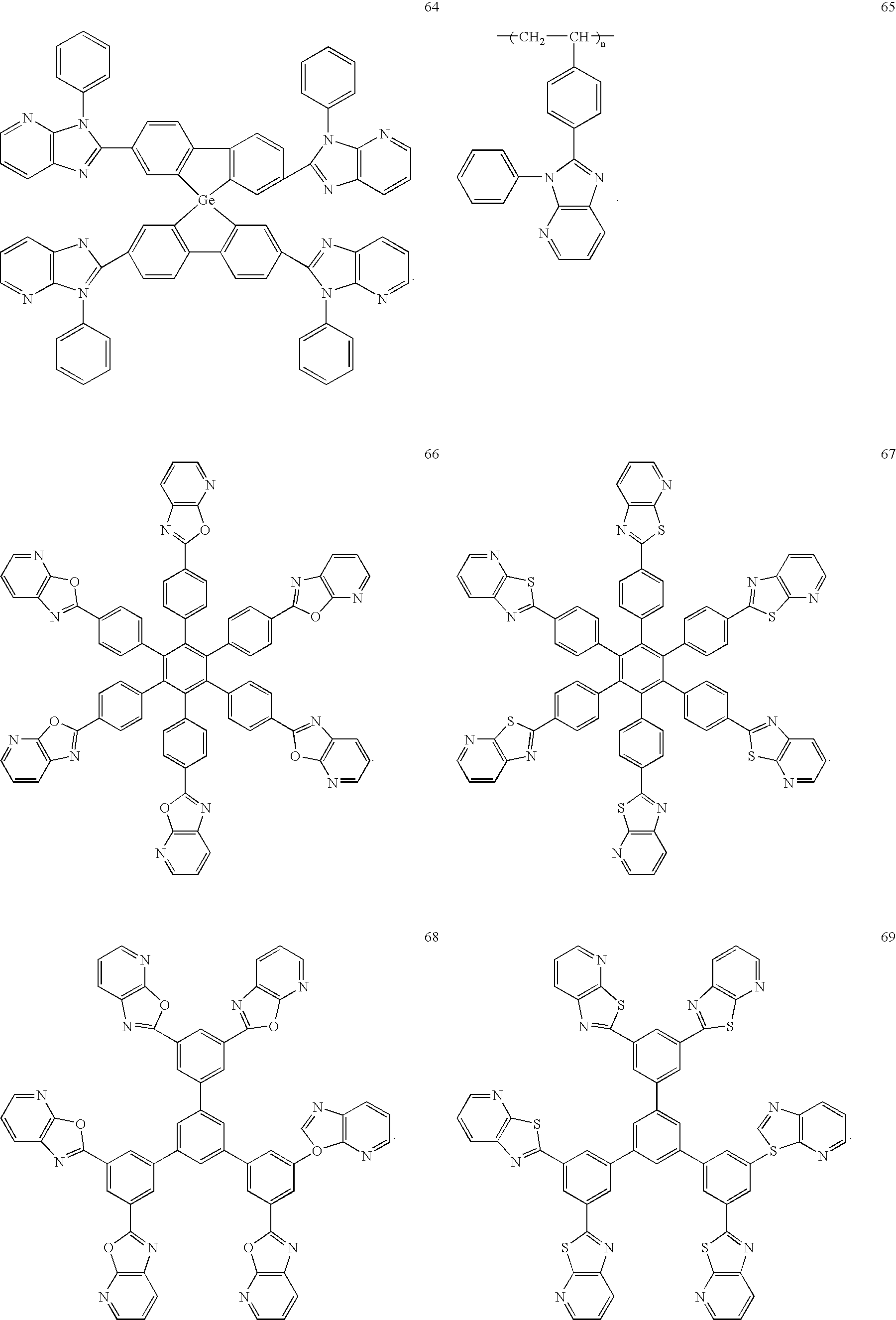

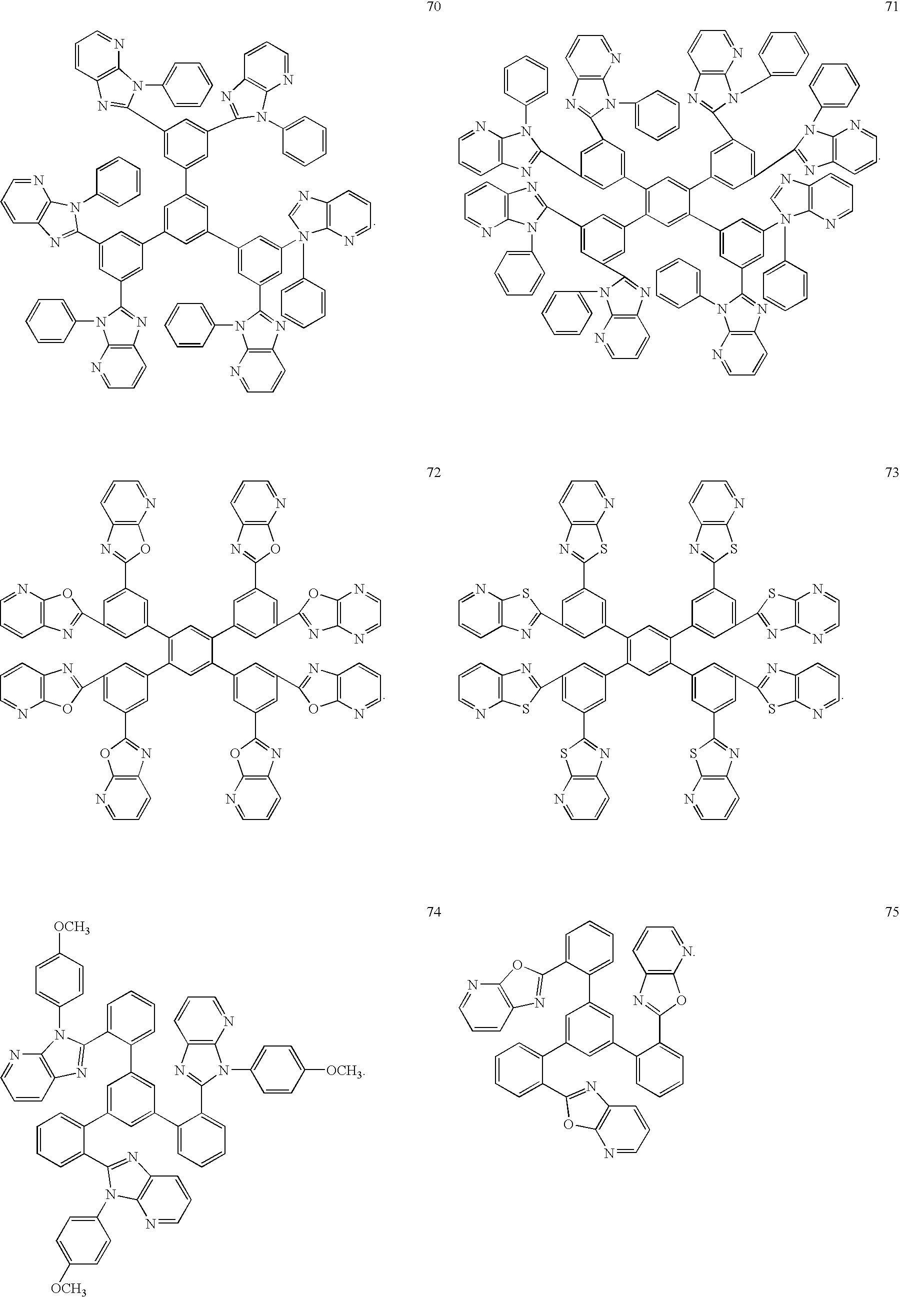

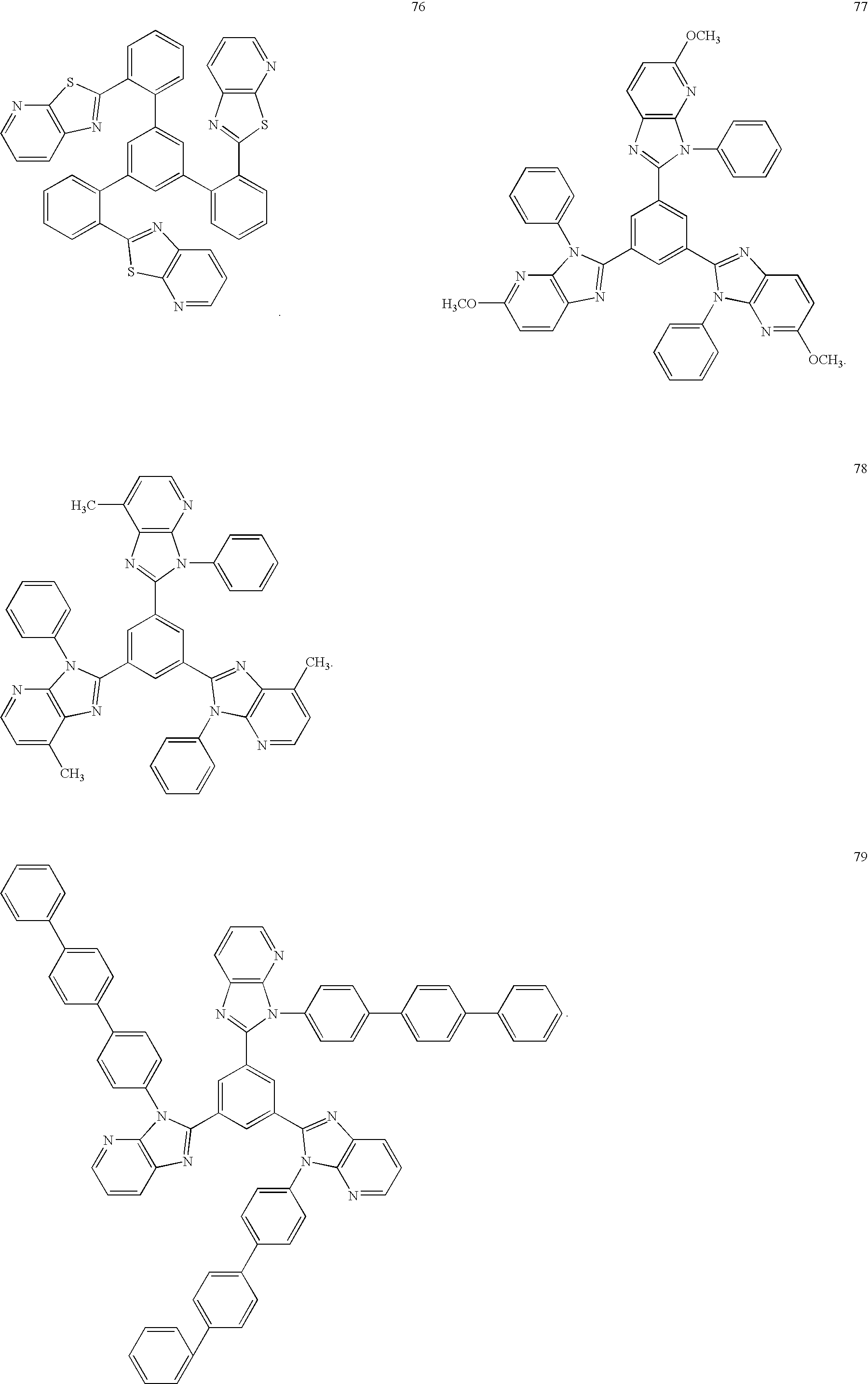

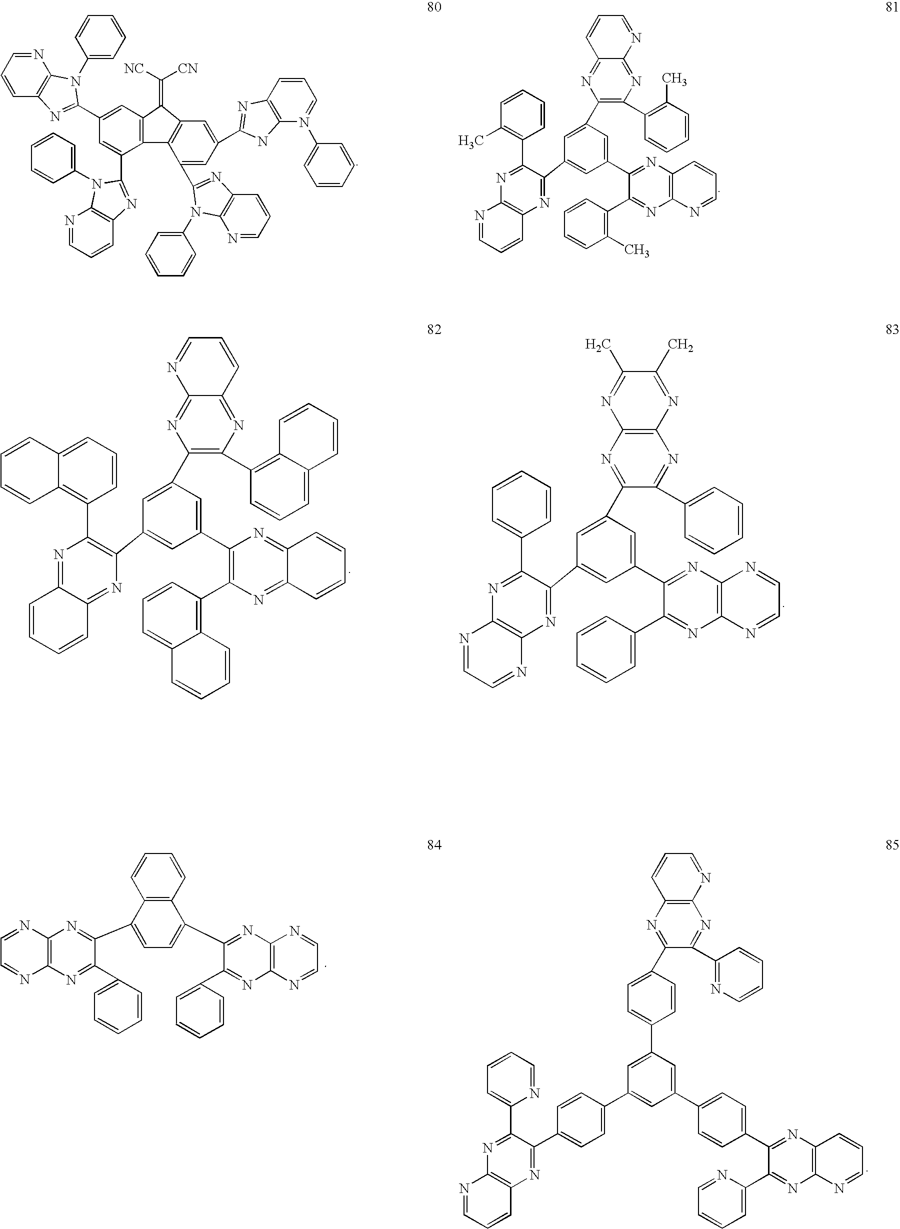

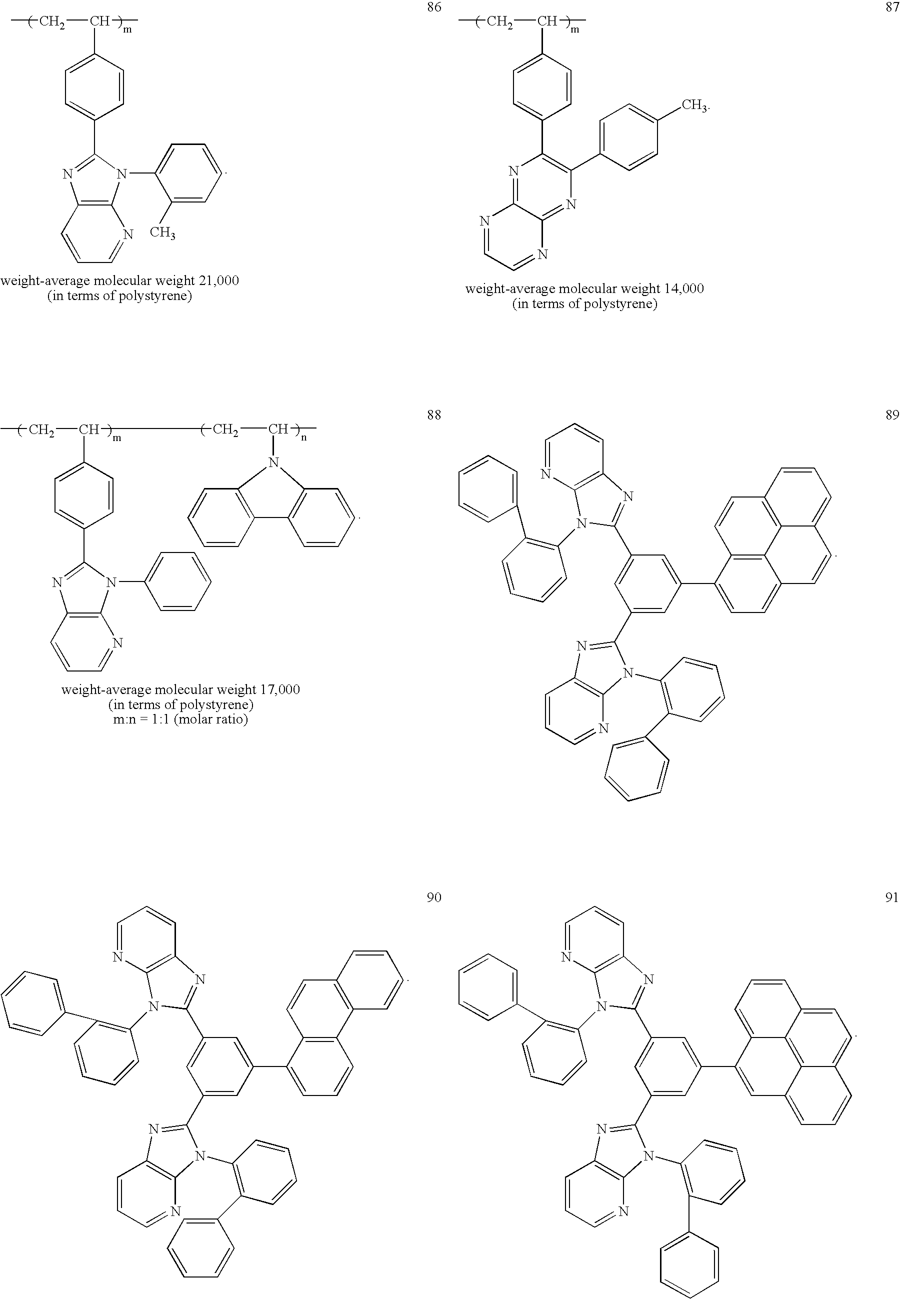

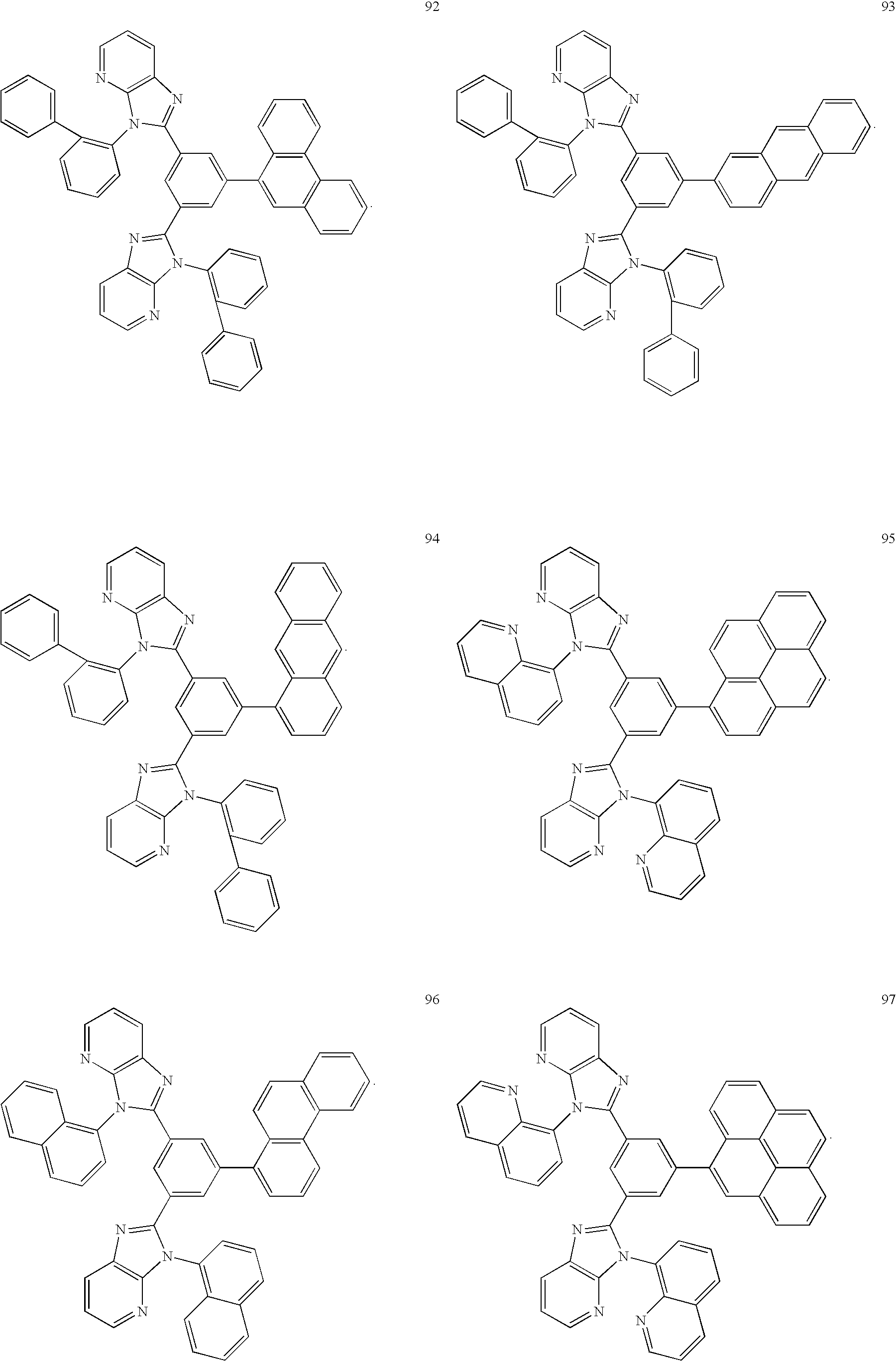

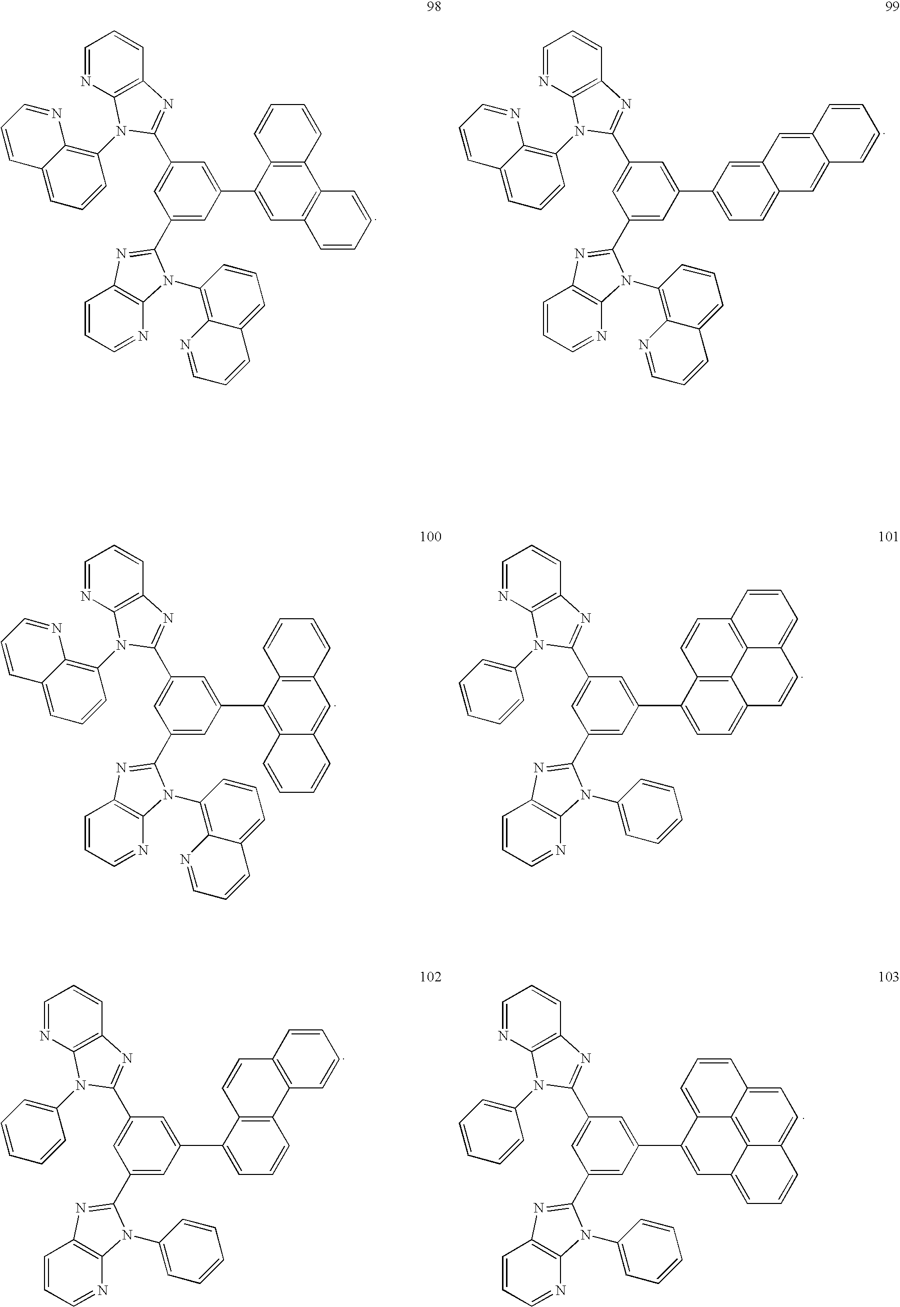

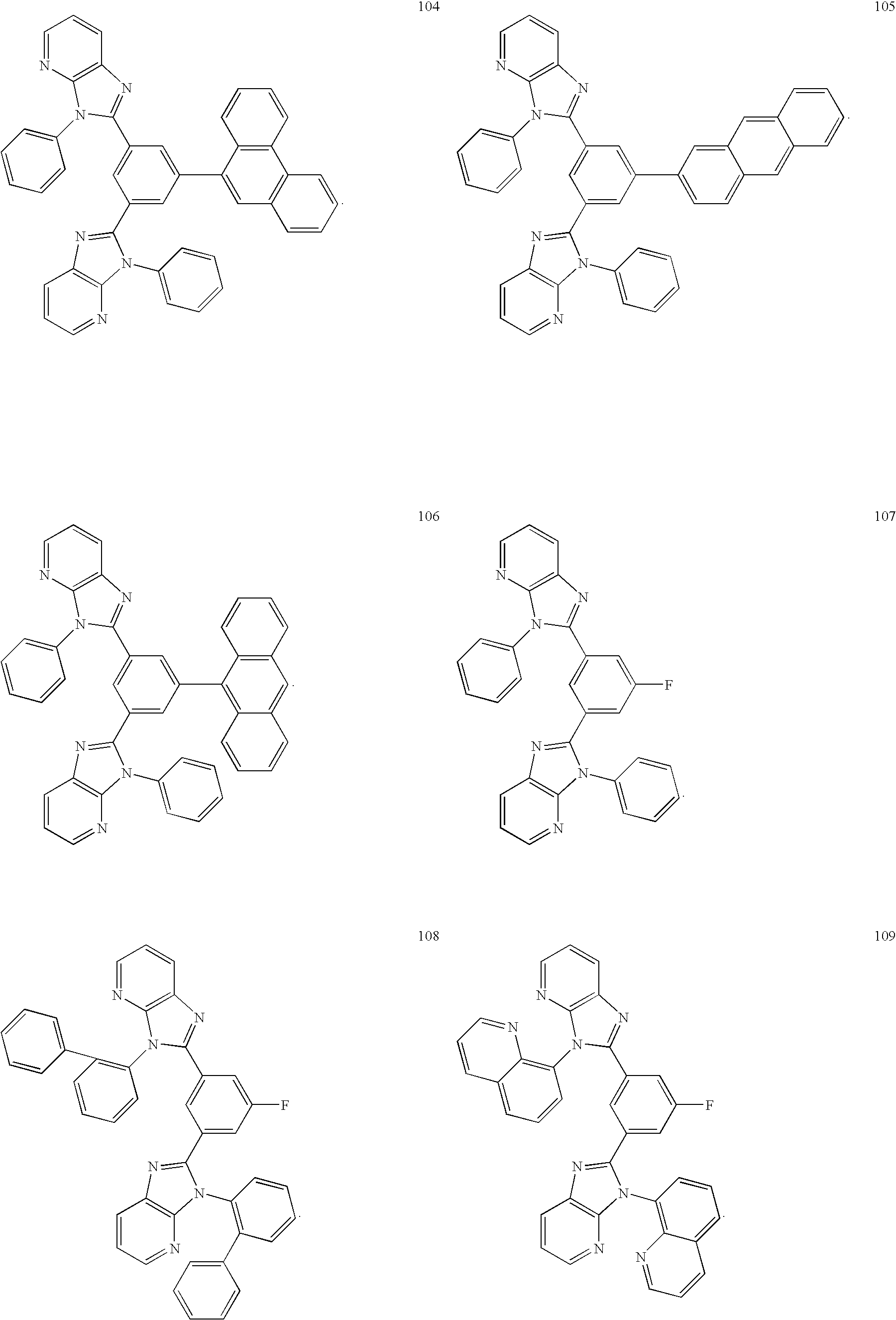

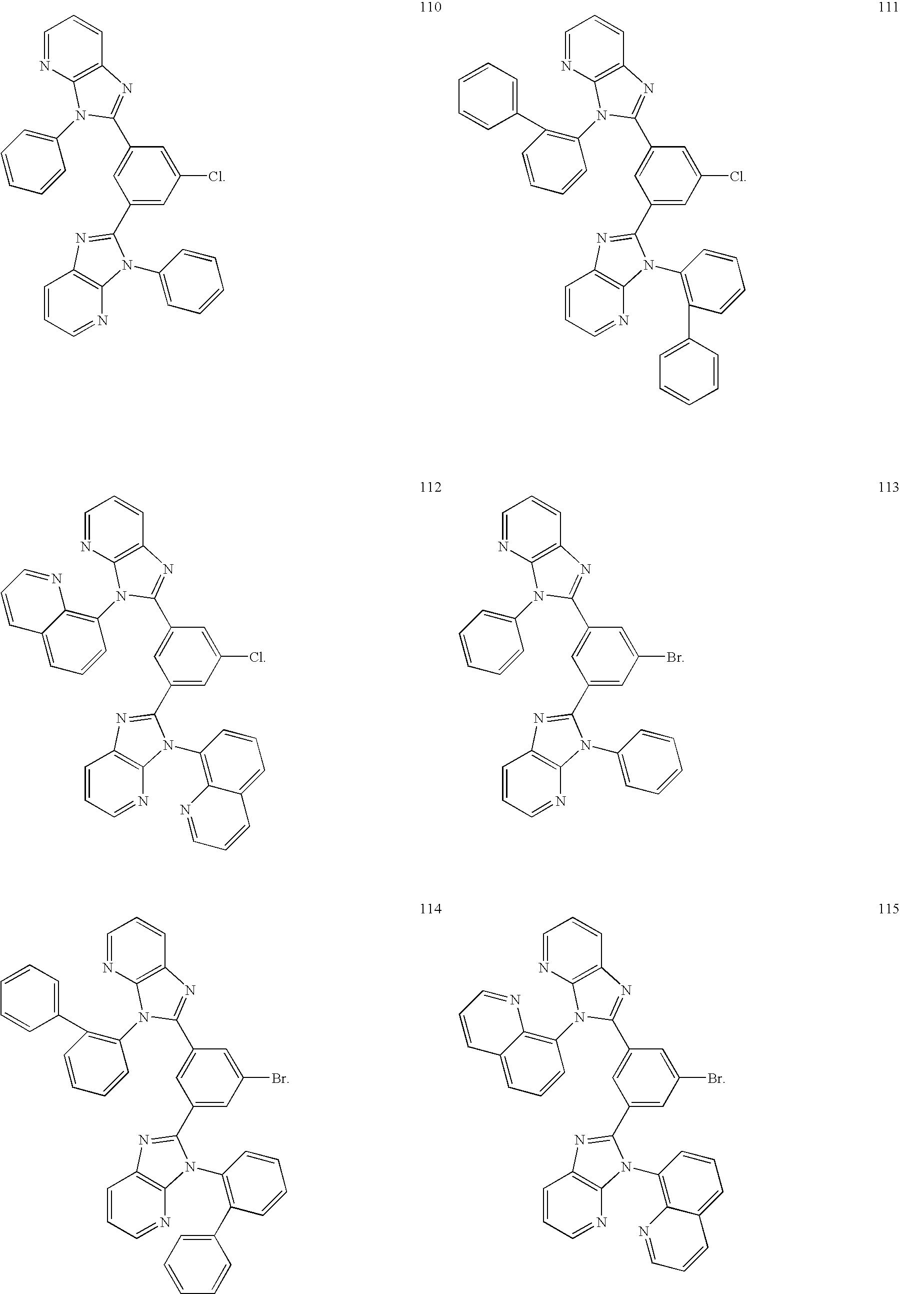

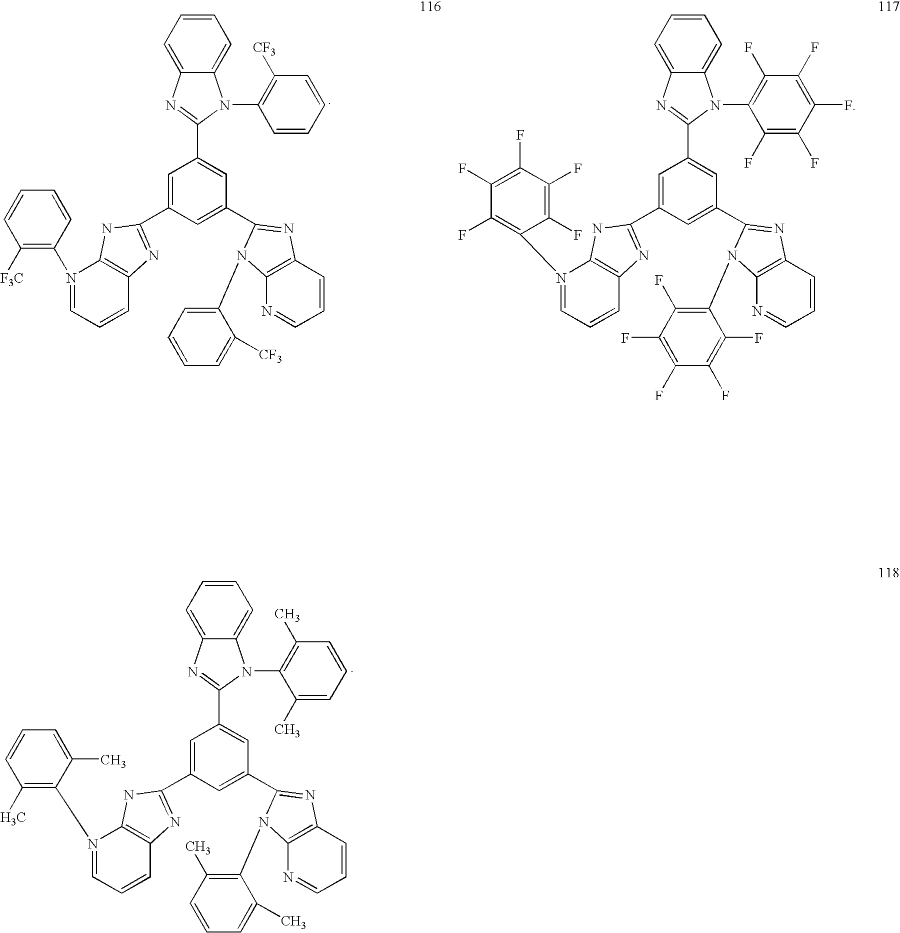

The compounds of the invention represented by formulae (I) to (XV) can be synthesized by reference to those methods which are described in, for example, JP-B-44-23025, JP-B-48-8842, JP-A-53-6331, JP-A-10-92578, U.S. Pat. Nos. 3,449,255 and 5,766,779, J. Am. Chem. Soc., 94, 2414 (1972), Helv. Chim. Acta, 63, 413 (1980), and Liebigs Ann. Chem., 1423 (1982).

Methods for synthesizing the compounds of the invention are described below by reference to specific examples.

### SYNTHESIS EXAMPLE 1

### Synthesis of Illustrative Compound 2

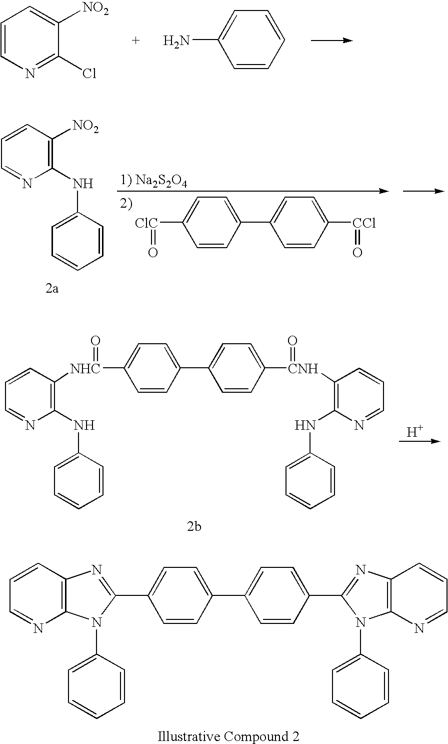

### 1-1. Synthesis of Compound 2a

50.8 g (0.320 mol) of 2-chloro-3-nitropyridine, 90.8 g (0.657 mol) of potassium carbonate, 7.90 g (0.0416 mol) of copper (I) iodide and 300 ml of toluene were stirred at room temperature under a nitrogen atmosphere, and 45.7 g (0.490 mol) of aniline was added thereto. After refluxing under heating for 5 hours, the reaction solution was filtered, and the filtrate was concentrated under reduced pressure. After purification of the concentrate by silica gel column chromatography (developing solvent: chloroform), the purified product was recrystallized from chloroform/hexane to obtain 45.7 g (0.21 mol) of compound 2a. Yield: 66%.

### 1-2. Synthesis of Compound 2b

17.0 g (0.0790 mol) of compound 2a was dissolved in 170 ml of tetrahydrofuran and stirred at room temperature under a nitrogen atmosphere, and a solution of 69.0 g (0.396 mol) of sodium hydrosulfite in 220 ml of water was dropwise added thereto. After stirring the mixture for 1 hour, 170 ml of ethyl acetate was added thereto, then a solution of 13.6 g (0.162 mmol) of sodium hydrogencarbonate in 140 ml of water was dropwise added thereto. Further, a solution of 10.0 g (0.0358 mol) of 4,4′-biphenyldicarbonyl chloride in 100 ml of ethyl acetate was dropwise added thereto, followed by stirring at room temperature for 5 hours. A precipitated solid was collected by filtration and washed with successive, water and ethyl acetate to obtain 16.0 g (0.0277 mol) of compound 2b. Yield: 77%.

### 1-3. Synthesis of Illustrative Compound 2

300 ml of xylene was added to a mixture of 10.0 g (0.0173 mol) of compound 2b and 2.3 g of p-toluenesulfonic acid monohydrate, and the resultant mixture was refluxed under heating for 6 hours in a nitrogen atmosphere to azeotropically dehydrate. The reaction solution was cooled to a room temperature, and a precipitated solid was collected by filtration and recrystallized from dimethylformamide/acetonitrile to obtain 5.20 g (9.62 mmol) of illustrative compound 2. Yield: 57%.

Melting point: 298-300° C.

### SYNTHESIS EXAMPLE 2

### Synthesis of Illustrative Compound 18

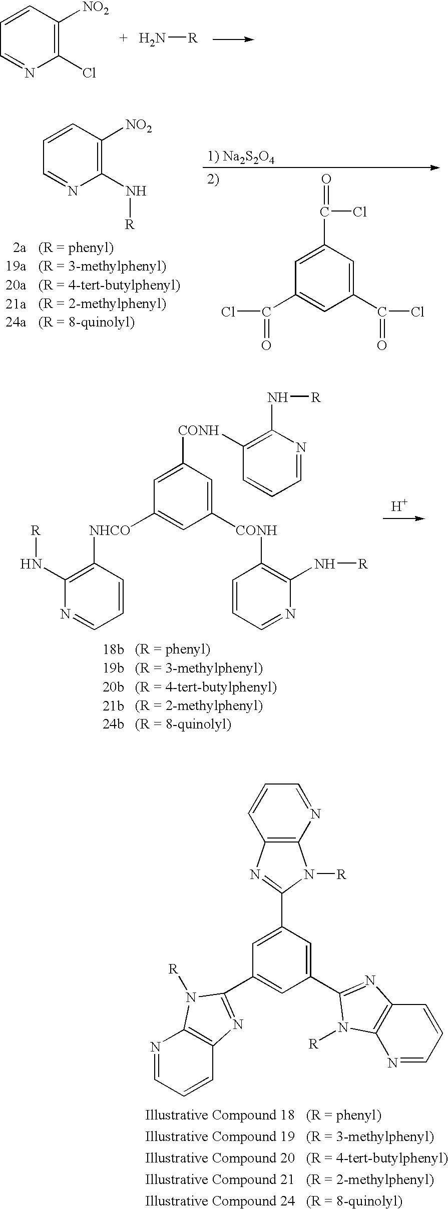

### 2-1. Synthesis of Compound 18b

15.0 g (0.0697 mol) of compound 2a was dissolved in 150 ml of tetrahydrofuran and stirred at room temperature under a nitrogen atmosphere, and a solution of 60.9 g (0.345 mol) of sodium hydrosulfite in 200 ml of water was dropwise added thereto. After stirring the mixture for 2 hours, 150 ml of ethyl acetate was added thereto, then a solution of 12.0 g (0.143 mol) of sodium hydrogencarbonate in 120 ml of water was dropwise added thereto. Further, a solution of 5.2 g (0.0196 mol) of trimesic acid chloride in 50 ml of ethyl acetate was dropwise added thereto, followed by stirring at room temperature for 3 hours. Then, a saturated saline was added to the reaction solution and, after extracting with ethyl acetate, the organic phase was washed with a saturated saline, and the organic phase was dried over anhydrous magnesium sulfate. Subsequently, the solvent was distilled off under reduced pressure, and the residue was purified by silica gel column chromatography (developing solvent: chloroform/methanol=10/1 (vol/vol)), followed by recrystallization from dimethylformamide/acetonitrile to obtain 4.1 g (5.76 mmol) of compound 18b. Yield: 29%.

### 2-2. Synthesis of Illustrative Compound 18

100 ml of xylene was added to a mixture of 3.70 g (5.20 mmol) of compound 18b and 0.7 g of p-toluenesulfonic acid monohydrate, and the resultant mixture was refluxed under heating for 3 hours in a nitrogen atmosphere to azeotropically dehydrate. The reaction solution was cooled to room temperature, the solvent was distilled off under reduced pressure, and the residue was purified by silica gel column chromatography (developing solvent: chloroform/methanol=20/1 (vol/vol)), followed by recrystallization from chloroform/methanol to obtain 1.70 g (2.58 mmol) of illustrative compound 18. Yield: 50%. Melting point: 279-282° C.

### SYNTHESIS EXAMPLE 3

### Synthesis of Illustrative Compound 19

### 3-1. Synthesis of Compound 19a

50.0 g (0.315 mol) of 2-chloro-3-nitropyridine, 90.8 g (0.657 mol) of potassium carbonate, 7.90 g (0.0416 mol) of copper (I) iodide and 300 ml of toluene were stirred at room temperature under a nitrogen atmosphere, and 45.0 g (0.420 mol) of m-toluidine was added thereto. After refluxing under heating for 8 hours, the reaction solution was filtered, and the filtrate was concentrated under reduced pressure. After purification of the concentrate by silica gel column chromatography (developing solvent: chloroform), the purified product was recrystallized from chloroform/hexane to obtain 51.0 g (0.222 mol) of compound 19a. Yield: 71%.

### 3-2. Synthesis of Compound 19b

32.5 g (0.142 mol) of compound 19a was dissolved in 320 ml of tetrahydrofuran and stirred at room temperature under a nitrogen atmosphere, and a solution of 124 g (0.712 mol) of sodium hydrosulfite in 320 ml of water was dropwise added thereto, followed by adding 100 ml of methanol. After stirring the mixture for 1 hour, 380 ml of ethyl acetate was added thereto, then a solution of 24.4 g (0.290 mol) of sodium hydrogencarbonate in 55 ml of water was dropwise added thereto. Further, a solution of 10.5 g (0.0396 mol) of trimesic acid chloride in 100 ml of ethyl acetate was dropwise added thereto, followed by stirring at room temperature for 3 hours. A saturated saline was added to the reaction solution and, after extracting with ethyl acetate, the organic phase was washed with a saturated saline, and the organic phase was dried over anhydrous magnesium sulfate. The solvent was distilled off under reduced pressure, and the residue was purified by silica gel column chromatography (developing solvent: chloroform/methanol=10/1 (vol/vol)) to obtain 10.2 g (0.0135 mol) of compound 19b. Yield: 34%.

### 3-3. Synthesis of Illustrative Compound 19

50 ml of xylene was added to a mixture of 3.30 g (4.38 mmol) of compound 19b and 0.5 g (2.63 mmol) of p-toluenesulfonic acid monohydrate, and the resultant mixture was refluxed under heating for 3 hours in a nitrogen atmosphere to azeotropically dehydrate. The reaction solution was cooled to a room temperature, and the solvent was distilled off. The residue was purified by silica gel column chromatography (developing solvent: chloroform/methanol=20/1 (vol/vol)), the purified product was recrystallized from chloroform/methanol to obtain 1.97 g (2.81 mmol) of illustrative compound 19. Yield: 64%.

Melting point: 258-259° C.

### SYNTHESIS EXAMPLE 4

### Synthesis of Illustrative Compound 20

### 4-1. Synthesis of Compound 20a

45.5 g (0.286 mol) of 2-chloro-3-nitropyridine, 81.1 g (0.587 mol) of potassium carbonate, 7.10 g (0.0373 mol) of copper (I) iodide and 300 ml of toluene were stirred at room temperature under a nitrogen atmosphere, and 40.0 g (0.268 mol) of 4-tert-butylaniline was added thereto. After refluxing under heating for 8 hours, the reaction solution was filtered, and the filtrate was concentrated under reduced pressure. After purification of the concentrate by silica gel column chromatography (developing solvent: chloroform), the purified product was recrystallized from chloroform/hexane to obtain 52.0 g (0.192 mol) of compound 20a. Yield: 72%.

### 4-2. Synthesis of Compound 20b

34.8 g (0.128 mol) of compound 20a was dissolved in 350 ml of tetrahydrofuran and stirred at room temperature under a nitrogen atmosphere, and a solution of 112 g (0.643 mol) of sodium hydrosulfite in 320 ml of water was dropwise added thereto, followed by adding 90 ml of methanol. After stirring the mixture for 1 hour, 350 ml of ethyl acetate was added thereto, then a solution of 22.0 g (0.262 mol) of sodium hydrogencarbonate in 50 ml of water was dropwise added thereto. Further, a solution of 9.5 g (0.0358 mol) of trimesic acid chloride in 90 ml of ethyl acetate was dropwise added thereto, followed by stirring at room temperature for 2 hours. A saturated saline was added to the reaction solution and, after extracting with ethyl acetate, the organic phase was washed with a saturated saline, and the organic phase was dried over anhydrous magnesium sulfate. The solvent was distilled off under reduced pressure, and the residue was purified by silica gel column chromatography (developing solvent: chloroform/methanol=10/1 (vol/vol)) to obtain 12.0 g (0.0136 mol) of compound 20b. Yield: 38%.

### 4-3. Synthesis of Illustrative Compound 20

50 ml of xylene was added to a mixture of 3.00 g (3.41 mmol) of compound 20b and 0.3 g (1.58 mmol) of p-toluenesulfonic acid monohydrate, and the resultant mixture was refluxed under heating for 3 hours in a nitrogen atmosphere to azeotropically dehydrate. The reaction solution was cooled to a room temperature, and a precipitated solid was collected by filtration and recrystallized from chloroform/methanol to obtain 2.06 g (2.49 mmol) of illustrative compound 20. Yield: 73%.

Melting point: above 300° C.

### SYNTHESIS EXAMPLE 5

### Synthesis of Illustrative Compound 21

### 5-1. Synthesis of Compound 21a

50.0 g (0.315 mol) of 2-chloro-3-nitropyridine, 90.8 g (0.657 mol) of potassium carbonate, 7.90 g (0.0416 mol) of copper (I) iodide and 300 ml of toluene were stirred at room temperature under a nitrogen atmosphere, and 45.0 g (0.420 mol) of o-toluidine was added thereto. After refluxing under heating for 8 hours, the reaction solution was filtered, and the filtrate was concentrated under reduced pressure. After purification of the concentrate by silica gel column chromatography (developing solvent: chloroform), the purified product was recrystallized from chloroform/hexane to obtain 46.3 g (0.202 mol) of compound 21a. Yield: 64%.

### 5-2. Synthesis of Compound 21b

32.5 g (0.142 mol) of compound 21a was dissolved in 320 ml of tetrahydrofuran and stirred at room temperature under a nitrogen atmosphere, and a solution of 124 g (0.712 mmol) of sodium hydrosulfite in 320 ml of water was dropwise added thereto, followed by adding thereto 100 ml of methanol. After stirring the mixture for 1 hour, 380 ml of ethyl acetate was added thereto, then a solution of 24.4 g (0.290 mol) of sodium hydrogencarbonate in 55 ml of water was dropwise added thereto. Further, a solution of 10.5 g (0.0396 mol) of trimesic acid chloride in 100 ml of ethyl acetate was dropwise added thereto, followed by stirring at room temperature for 3 hours. A saturated saline was added to the reaction solution and, after extracting with ethyl acetate, the organic phase was washed with a saturated saline, and the organic phase was dried over anhydrous magnesium sulfate. The solvent was distilled off under reduced pressure, and the residue was purified by silica gel column chromatography (developing solvent: chloroform/methanol=10/1 (vol/vol)) to obtain 8.5 g (0.0112 mol) of compound 21b. Yield: 28%.

### 5-3. Synthesis of Illustrative Compound 21

50 ml of xylene was added to a mixture of 3.30 g (4.38 mmol) of compound 21b and 0.5 g (2.63 mmol) of p-toluenesulfonic acid monohydrate, and the resultant mixture was refluxed under heating for 7 hours in a nitrogen atmosphere to azeotropically dehydrate. The reaction solution was cooled to a room temperature, and the solvent was distilled off under reduced pressure. The resulting residue was purified by silica gel column chromatography (developing solvent: chloroform/methanol=20/1 (vol/vol)), and the purified product was recrystallized from chloroform/acetonitrile to obtain 2.02 g (2.88 mmol) of illustrative compound 21. Yield: 66%. Melting point: 250° C.

### SYNTHESIS EXAMPLE 6

### Synthesis of Illustrative Compound 24

### 6-1. Synthesis of Illustrative Compound 24a

59.0 g (0.347 mol) of 2-chloro-3-nitropyridine, 105 g (0.760 mol) of potassium carbonate, 9.40 g (0.0494 mol) of copper (I) iodide and 300 ml of toluene were stirred at room temperature under a nitrogen atmosphere, and 75.0 g (0.520 mol) of 8-aminoquinoline was added thereto. After refluxing under heating for 16 hours, the reaction solution was filtered, and the filtrate was concentrated under reduced pressure. After purification of the concentrate by silica gel column chromatography (developing solvent: chloroform), the purified product was recrystallized from chloroform/hexane to obtain 27.0 g (0.102 mol) of compound 24a. Yield: 29%.

### 6-2. Synthesis of Compound 24b

25.0 g (93.9 mmol) of compound 24a was dissolved in 220 ml of tetrahydrofuran and stirred at room temperature under a nitrogen atmosphere, and a solution of 82.2 g (0.472 mol) of sodium hydrosulfite in 420 ml of water was dropwise added thereto, followed by adding thereto 70 ml of methanol. After stirring the mixture for 1 hour, 380 ml of ethyl acetate was added thereto, then a solution of 24.4 g (0.290 mol) of sodium hydrogencarbonate in 55 ml of water was dropwise added thereto. Further, a solution of 7.55 g (28.4 mmol) of trimesic acid chloride in 100 ml of ethyl acetate was dropwise added thereto, followed by stirring at room temperature for 3 hours. A saturated saline was added to the reaction solution and, after extracting with ethyl acetate, the organic phase was washed with a saturated saline, and the organic phase was dried over anhydrous magnesium sulfate. The solvent was distilled off under reduced pressure, and the residue was purified by silica gel column chromatography (developing solvent: chloroform/methanol=10/1 (vol/vol)) to obtain 7.86 g (9.09 mmol) of compound 24b. Yield: 32%.

### 6-3. Synthesis of Illustrative Compound 24

100 ml of xylene was added to a mixture of 5.00 g (5.78 mmol) of compound 24b and 0.5 g (2.63 mmol) of p-toluenesulfonic acid monohydrate, and the resultant mixture was refluxed under heating for 5 hours in a nitrogen atmosphere to azeotropically dehydrate. The reaction solution was cooled to room temperature, and the solvent was distilled off under reduced pressure. The resulting residue was purified by silica gel column chromatography (developing solvent: chloroform/methanol=20/1 (vol/vol)), and the purified product was recrystallized from chloroform/acetonitrile to obtain 1.87 g (2.31 mmol) of illustrative compound 24. Yield: 40%. Melting point: 384° C.

### SYNTHESIS EXAMPLE 7

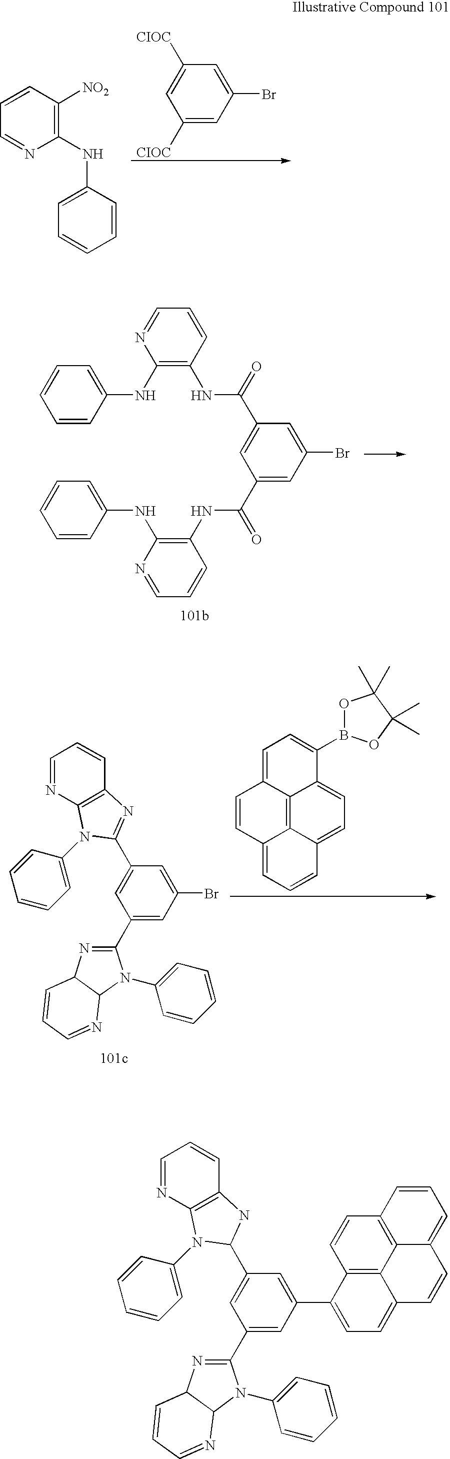

### 7-1. Synthesis of Compound 101b

50.0 g (0.232 mol) of compound 2a was dissolved in 500 ml of tetrahydrofuran and, under stirring in a nitrogen atmosphere, a solution of 200 g (1.149 mol) of sodium hydrosulfite in 700 ml of water was dropwise added thereto, followed by adding thereto 20 ml of methanol. After stirring the mixture for 1 hour, 500 ml of ethyl acetate was added thereto, then a solution of 40 g (0.476 mol) of sodium hydrogencarbonate in 400 ml of water was dropwise added thereto. Further, a solution of 65.4 g (0.232 mol) of 5-bromoisophthaloyl chloride in 150 ml of ethyl acetate was dropwise added thereto, followed by stirring at room temperature for 5 hours. Then, the mixture was extracted with ethyl acetate, and the extract was washed with successive, water and a saturated saline, and dried over anhydrous magnesium sulfate, followed by distilling off the solvent under reduced pressure. The resulting residue was purified by silica gel column chromatography (developing solvent: chloroform), and the purified product was recrystallized from chloroform/hexane to obtain 29.6 g (0.051 mol) of compound 10b. Yield: 22%.

### 7-2. Synthesis of Compound 101c

30 g (0.05 mol) of compound 101b was dissolved in 1 liter of xylene, and 4.7 g (0.025 mol) of p-toluenesulfonic acid monohydrate was added thereto, followed by refluxing the mixture under heating for 2 hours in a nitrogen atmosphere to conduct azeotropic dehydration. After cooling the reaction solution to room temperature, a precipitated solid was collected by filtration and recrystallized from ethanol/chloroform to obtain 16.3 g (0.03 mol) of compound 101c. Yield: 58%.

### 7-3. Synthesis of Illustrative Compound 101

500 mg (0.92 mmol) of compound 101c and 332 mg (1.01 mmol) of compound 101d were suspended in a mixture of 20 ml of ethylene glycol dimethyl ether and 10 ml of water. To this suspension were added 214.5 mg (2.02 mmol) of sodium carbonate, 15 mg of palladium carbon and 12 mg of triphenylphosphine, and the resulting mixture was refluxed under heating for 2 hours. After discontinuing heating, the catalyst was removed by hot filtration, and the filtrate was extracted with ethyl acetate and dried over magnesium sulfate, followed by distilling off the solvent. The residue was recrystallized from chloroform to obtain 180 mg (0.27 mmol) of illustrative compound 101. Yield: 29%.

A preferred embodiment of the photodetector of the invention is described below.

The photodetector in the invention has a photoelectric converting layer capable of absorbing light and converting it to electron and has an interelectrode material and electrodes for separating the electron. As a preferred constitution thereof, there is an embodiment, which comprises a substrate having formed thereon a single photodetector. Examples of the embodiment include a constitution [1] which comprises, from the bottom, a lower electrode layer, an electron transporting material layer, a hole transporting material layer and a transparent electrode and a constitution [2] which comprises a lower electrode layer, a hole transporting material layer, an electron transporting material layer and a transparent electrode. However, the invention is not limited by these. For example, the electron transporting material layer may be divided into two or more layers, and the hole transporting layer may be divided into two or more layers. Examples of this embodiment include a constitution [3] which comprises a lower electrode layer, an electron transporting material layer, an electron transporting material layer, a hole transporting material layer and a transparent electrode, a constitution [4] which comprises a lower electrode layer, an electron transporting material layer, a hole transporting material layer, a hole transporting material layer and a transparent electrode, and a constitution [5] which comprises a lower electrode layer, an electron transporting material layer, an electron transporting material layer, a hole transporting material layer, a hole transporting material layer and a transparent electrode. Further, in the case where two or photodetectors are formed on the substrate, it is fundamentally possible to employ a combination of the above-mentioned constitutions. That is, there are illustrated, for example, a combination of [1] and [1] which comprises, from the bottom, a lower electrode layer, an electron transporting material layer, a hole transporting material layer, a transparent electrode, an interlayer insulating membrane, a lower electrode layer (transparent electrode), an electron transporting material layer, a hole transporting material layer and a transparent electrode, and a combination of [1] and [2] which comprises, from the bottom, a lower electrode layer, an electron transporting material layer, a hole transporting material layer, a transparent electrode, an interlayer insulating membrane, a lower electrode layer (transparent electrode), a hole transporting material layer, an electron transporting material layer and a transparent electrode. These multiple layers may be constituted by an arbitrary combination of constitutions selected from [1], [2], [3], [4] and [5], or by an arbitrary combination of a constitution other than [1], [2], [3], [4] and [5] with the constitution [1], [2], [3], [4] or [5]. Formation of at least two photodetectors on a substrate serves to increase light-utilizing efficiency per unit area in comparison with the case of forming a single photodetector, thus being preferred in the invention. Further, formation of at least three photodetectors on a substrate serves to more enhance light-utilizing efficiency, thus being particularly preferred in the invention. In the case of forming, particularly, at least three photodetectors, a blue light photodetector, a green light photodetector and a red light photodetector can be formed, which permits formation of a full color imaging device. Thus, such formation is extremely preferred in the invention. Naturally, examples of the constitution wherein at least three photodetectors are formed on a substrate include, as with the case of forming two photodetectors, any combination of members selected from among [1] and [2] and any combination of other constitution and [1] or [2]. Other combinations than them may, of course, be employed.

The material to be used as the electrode may be any combination of members selected from among, for example, Li, Na, Mg, K, Ca, Rb, Sr, Cs, Ba, Fr, Ra, Sc, Ti, Y, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Al, Ga, In, Tl, Si, Ge, Sn, Pb, P, As, Sb, Bi, Se, Te, Po, Br, I, At, B, C, N, F, O, S and N. However, particularly preferred in the invention are Al, Pt, W, Au, Ag, Ta, Cu, Cr, Mo, Ti, Ni, Pd and Zn.

Also, the hole transporting material in the invention may be an inorganic material or an organic material. In the invention, however, incorporation of an organic material is particularly preferred and, therefore, preferably usable examples are illustrated below. For example, poly-N-vinylcarbazole derivatives, polyphenylenevinylene derivatives, polyphenylene, polythiophene, polymethylphenylsilane, polyaniline, triazole derivatives, oxadiazole derivatives, imidazole derivatives, polyarylalkane derivatives, pyrazoline derivatives and pyrazolone derivatives, phenylenediamine derivatives, arylamine derivatives, amino-substituted chalcone derivatives, oxazole derivatives, carbazole derivatives, styrylanthracene derivatives, fluorenone derivatives, hydrazone derivatives, stilbene derivatives, porphyrin derivatives (e.g., phthalocyanine), aromatic tertiary amine compounds and styrylamine compounds, butadiene compounds, benzidine derivatives, polystyrene derivatives, triphenylmethane derivatives, tetraphenylbenzyne derivatives and star burst polyamine derivatives can be used. Also, use of an organic dye is extremely preferred. It is possible to impart a light-absorbing structure to the above-mentioned materials and, in addition, there can preferably be used metal complex dyes, cyanine-based dyes, merocyanine-based dyes, phenylxanthene-based dyes, triphenylmethane-based dyes, rhodacyanine-based dyes, xanthene-based dyes, large ring azaanurene-based dyes, azulene-based dyes, naphthoquinone- or anthraquinone-based dyes, condensed polycyclic aromatic compounds such as anthracene and pyrene, chain compounds wherein aromatic or hetero ring compounds are condensed, two nitrogen-containing hetero rings such as quinoline, benzothiazole and benzoxazole, and cyanine-analogous dyes bound via a squarylium group and a croconic methine group. As the metal complex dyes, dithiol metal complex dyes, metal phthalocyanine dyes, metal porphyrin dyes or ruthenium complex dyes are preferred, with ruthenium complex dyes being particularly preferred. Examples of the ruthenium complex dyes include those complex dyes, which are described in U.S. Pat. Nos. 4,927,721, 4,684,537, 5,084,365, 5,350,644, 5,463,057 and 5,525,440, JP-A-7-249790, JP-T-10-504512 (the term “JP-T” as used herein means a published Japanese translation of a PCT patent application), WO98/50393 and JP-A-2000-26487. Specific examples of polymethine dyes such as cyanine dyes, merocyanine dyes and squarylium dyes are those dyes which are described in JP-A-11-35836, JP-A-11-67285, JP-A-11-86916, JP-A-11-97725, JP-A-158395, JP-A-163378, JP-A-11-214730, JP-A-11-214731, JP-A-11-238905, JP-A-2000-26487, European Patent Nos. 892411, 911841 and 991092.

Additionally, in the invention, these materials may be incorporated in a binder as needed. Examples of the polymer binder to be used for such purpose include polyvinyl chloride, polycarbonate, polystyrene, polymethyl methacrylate, polybutyl methacrylate, polyester, polysulfone, polyphenylene oxide, polybutadiene, hydrocarbon resin, ketone resin, phenoxy resin, polyamide, ethyl cellulose, polyvinyl acetate, ABS resin, polyurethane, melamine resin, unsaturated polyester, alkyd resin, epoxy resin, silicone resin, polyvinyl butyral and polyvinyl acetal.

A material for the transparent electrode in the invention may fundamentally be any. Examples thereof include a metal, an alloy, a metal oxide, an organic, electrically conductive compound and a mixture thereof, and specific examples thereof include electrically conductive metal oxides such as tin oxide, zinc oxide, indium oxide, indium zinc oxide (IZO), indium tin oxide (ITO); metals such as gold, platinum, silver, chromium and nickel; mixtures or laminates of these metals and electrically conductive metal oxides; inorganic electrically conductive substances such as copper iodide and copper sulfide; organic electrically conductive materials such as polyaniline, polythiophene and polypyrrole; and laminates of these and ITO. Also, those which are described in detail in “Tomei Dodenmaku No Shintenkai” supervised by Yutaka Sawada (published by CMC in 1999), “Tomei Dodenmaku No Gijutsu” written by Nihon Gakujutsu Sinkokai (published by Ohm in 1999) may be used. In the invention, however, it is preferred in the invention to incorporate one of ITO, IZO, SnO₂, ATO, ZnO, TiO₂ and FTO. The transmittance of the transparent electrode in the invention is preferably 60% or more, more preferably 80% or more, still more preferably 90% or more, yet more preferably 95% or more at an absorption peak wavelength of the photoelectric converting layer. The surface resistance is preferably 10,000Ω/□ or less, more preferably 100Ω/□ or less, still more preferably 10Ω/□. As to the thickness, the thinner, the more preferred. The thickness is preferably 0.5 μm or less, more preferably 0.3 μm or less, still more preferably 0.15 μm or less.

The photodetector of the invention may fundamentally be formed in any method. Examples of the method for forming a film in vacuo include a resistance heating vacuum deposition apparatus, an RF sputtering apparatus, a DC sputtering apparatus, an opposed-target type sputtering apparatus, CVD, MBE and PLD which, however, do not limit the invention.

Also, it is desirable to provide a sealing layer in the photodetector of the invention for preventing invasion of moisture or oxygen into respective layers constituting the element. As such sealing material, there may be used a copolymer containing tetrafluoroethylene and at least one comonomer, a fluorine-containing copolymer having a cyclic structure in the main chain thereof, polyethylene, polypropylene, polymethyl methacrylate, polyimide, polyurea, polytetrafluoroethylene, polychlorotrifluoroethylene, polydichlorodifluoroethylene, a copolymer between chlorotrifluoroethylene and dichlorodifluoroethylene, a water-absorbing substance having a water absorption of 1% or more and a moisture-proof substance having a water absorption of 0.1% or less, a metal such as In, Sn, Pb, Au, Cu, Ag, Al, Ti or Ni, a metal oxide such as MgO, SiO, SiO₂, Al₂O₃, GeO, NiO, CaO, BaO, Fe₂O₃, Y₂O₃ or TiO₂, a metal fluoride such as MgF₂, LiF, AlF₃ or CaF₂, a liquid fluorocarbon such as perfluoroalkane, perfluoroamine or perfluoroether, and a product obtained by dispersing an absorbent capable of absorbing moisture or oxygen in the liquid fluorocarbon.

The substrate to be used in the invention is most preferably a Si substrate such as a Si wafer having mounted thereon a charge transfer device or a Si wafer having mounted thereon a CMOS image sensor-driving circuit. In addition, any of a semiconductor substrate, a glass substrate, a plastic substrate and the like may be used.

### EXAMPLES

The invention is described in detail by reference to Examples below which, however, do not limit the invention.

### Example 1

### Preparation of Photodetector A1 to A7

2.5-cm square Corning 1737 glass substrate was washed by applying ultrasonic wave in successive, acetone, Semico Clean and isopropyl alcohol (IPA) each for 15 minutes. After finally washing by boiling in IPA, the substrate was subjected to UV/O₃ washing. The substrate was moved to a sputtering chamber and was fixed to a substrate holder together with a mask having 2 patterns of 5 mm in ITO width and 5 mm in electrode-to-electrode distance, followed by reducing the pressure within the chamber to 3×10⁻5 Pa. ITO was sputtered on the substrate in a thickness of 0.2 μm. The resultant ITO had a surface resistance of 7Ω/□. This substrate was moved to an organic layer-vacuum depositing chamber, and the pressure within the chamber was reduced to 3×10⁻⁴ Pa. Subsequently, the following ruthenium complex was deposited at a deposition rate of 3 to 4 Å/sec in a thickness of 400 Å while rotating the substrate holder. Then, compound 119 was deposited in a thickness of 600 Å to form a film. Thereafter, A1 was film-formed in a thickness of 0.02 μm by a resistance heating vacuum deposition apparatus. Furthermore, ITO was again deposited thereon in a thickness of 0.20 μm (element A1). Elements A2 to A7 were prepared in the same manner as the element A1 except for changing the compound 119 to compound 21, compounds A, B, C and D, and Alq (tris-8-hydroxyquinoline aluminum), respectively. Also, compounds 119 and 21, compounds A, B, C and D and Alq were respectively deposited alone on a transparent glass in a thickness of 2000 Å to determine ionization potential by means of AC-1. (When the ionization potential was too high to measure by means of AC-1, the measurement was conducted by UPS.) Each of these elements A1 to A7 was irradiated with a white light for 1/100 second, and number of electrons generated from the current was calculated to determine quantum efficiency. The results thus obtained are shown in Table 1. Additionally, the test was conducted by applying a volt of 3V to the Al-fitted ITO (upper electrode) against ITO (lower electrode). In the case where current flows before irradiation with light, the current value was subtracted from the current value upon incidence of light to determine the quantum yield.

TABLE 1

| | Compound | | Compound | Compound | Compound | Compound | Compound |
|---|---|---|---|---|---|---|---|
| | A | Alq | 119 | B | C | D | 21 |
| Ionization | 5.3 | 5.8 | 6.1 | 6.1 | 6.2 | 6.3 | 7.5 |
| potential | | | | | | | |
| Quantum | 17% | 20% | 30% | 29% | 32% | 31% | 46% |
| efficiency | | | | | | | |

| | |
|---|---|
| | Compound A |
| 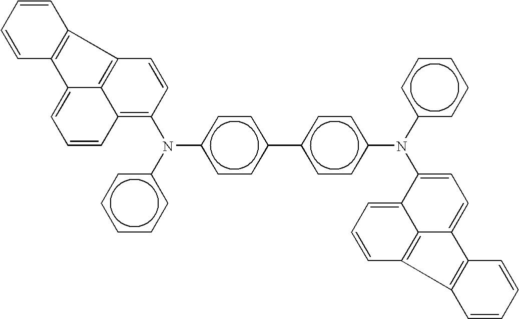 | |
| | Compound B |
| 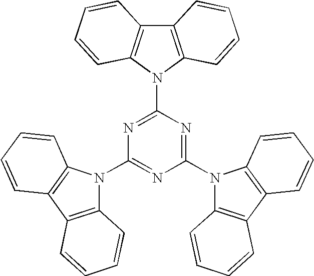 | |
| | Compound C |
| 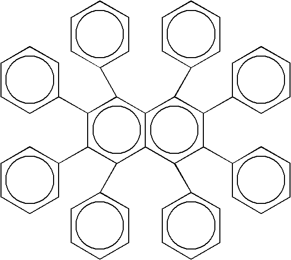 | |
| | Compound D |
| 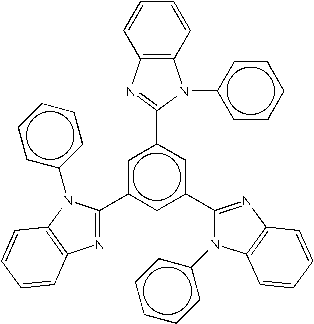 | |

| | |
|---|---|
| | Ruthenium Complex |
| 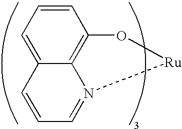 | |

As is apparent from Table 1, it is seen that the efficiency is more improved as the ionization potential of the compound increases. In particular, when the ionization potential is about 6.0 eV or more, the efficiency reaches as high as 30% and, when the ionization potential is 6.8 eV or more, the efficiency reaches as high as 46%.

### Example 2

### Preparation of Photodetector B1 to B7

A red light photodetector was prepared in the same manner as in each of elements A1 to A7 of Example 1 except for using the following zinc phthalocyanine in place of the ruthenium complex, and the element of Example 1 was laminated thereon. As a result of conducting the same evaluation as in Example 1 on the two elements, absolutely the same tendency as in Example 1 was obtained. Additionally, ionization potentials of ruthenium complex, zinc phthalocyanine and compound E are shown in Table 2.

TABLE 2

| | Ru | Zinc | Compound |
|---|---|---|---|
| | Complex | Phthalocyanine | E |
| Ionization | 5.1 | 5.1 | 5.8 |
| potential | | | |

| | |
|---|---|
| | Zinc Phthalocyanine |
| 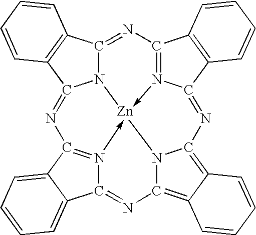 | |

### Example 3

### Preparation of Photodetector C1 to C7

An element using the following compound E was laminated in place of using the ruthenium complex used in each of the elements A1 to A7 of Example 1, and the same evaluation as in Example 1 was conducted. The results are shown in Table 3. It is seen from Table 3 that the material having the same ionization potential as, or less than, that of compound E suffered a serious reduction in the efficiency. That is, it is seen that the ionization potential of the electron transporting organic material to be used in the invention is desirably larger than the ionization potential of the hole transporting material. In particular, this is effective in a blue light photodetector. Needless to say, it is difficult to find such compound, and the invention has been achieved by overcoming the difficulty.

TABLE 3

| | Compound | | Compound | Compound | Compound | Compound | Compound |
|---|---|---|---|---|---|---|---|
| | A | Alq | 119 | B | C | D | 21 |
| Ionization | 5.3 | 5.8 | 6.1 | 6.1 | 6.2 | 6.3 | 7.5 |
| potential | | | | | | | |
| Quantum | 2% | 4% | 26% | 29% | 28% | 31% | 42% |
| efficiency | | | | | | | |

| | |
|---|---|
| | Compound E |
| 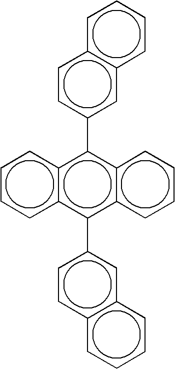 | |

### Example 4

### Preparation of Photodetector D1 to D7

Photodetectors were prepared in the same manner as in Example 1 except for using the following compound 77 in place of the ruthenium complex, and evaluated in the same manner as in Example 1, as a result, absolutely the same tendency as in Example 1 was obtained.

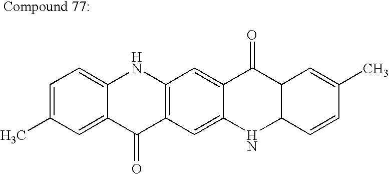

### Example 5

### Preparation of Photodetectors E1 to E7

In Example 4, after depositing m-MTDATA on ITO in a thickness of 20 nm and then depositing the compound 77 in a thickness of 100 nm, the material to be film-formed thereon in a thickness of 50 nm was varied among 7 kinds of materials (compounds 119 and 21, compounds A, B, C and D, and Alq (tris-8-hydroxyquinoline aluminum)), whereby seven elements were prepared. In all of these seven elements, the compound 78 was deposited and then Al was film-formed in a thickness of 0.02 μm by a resistance heating vacuum deposition apparatus. Furthermore, ITO was again film-formed thereon in a thickness of 0.20 μm. When these elements E1 to E7 were evaluated in the same manner as in Example 1, the same results as in Example 1 were obtained.

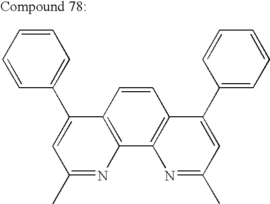

### Example 6

### Preparation of Photodetectors F1 to F6

The same ITO substrate as in Example 1 was prepared, m-MTDATA was deposited on the substrate in a thickness of 20 nm, the compound 77 was then deposited in a thickness of 100 nm, Alq (tris-8-hydroxyquinoline aluminum) was further deposited on these films in a thickness of 50 nm, and a material which was varied among 6 kinds of materials (compounds 119 and 21, and compounds A, B, C and D) was deposited thereon in a thickness of 20 nm, whereby six elements were prepared. Thereafter, Al was film-formed in a thickness of 0.02 μm by a resistance heating vacuum deposition apparatus, and ITO was again film-formed thereon in a thickness of 0.20 μm. When these elements were evaluated in the same manner as in Example 1, the same results as in Example 1 were obtained.

### Example 7

Elements were prepared by reversing the order of depositing organic materials for the top and bottom layers in Examples 5 and 6 (namely, such that the uppermost layer was m-MTDATA and the lowermost layer was the compound 78) and when these elements were evaluated, the same results as in Examples 5 and 6 were obtained. Incidentally, the direction of the bias applied here was opposite that of Example 5, because the electron was taken out into the upper electrode in Example 5 but taken out into the lower part in this Example.

### Example 8

### Preparation of Imaging Device

As the substrate for the charge transporting portion of the invention, the following one may be used.

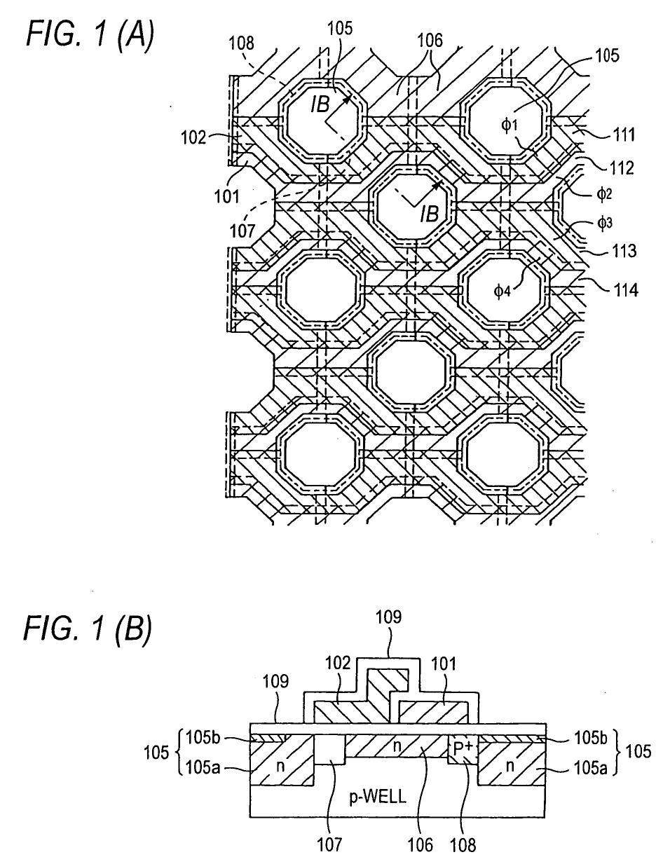

FIG. 1 (A) is a view showing a schematic constitution of a substrate for a charge transporting portion to be used in an embodiment of the invention. To describe one aspect of this system, a so-called honeycomb arrangement CCD (hereinafter referred to as “honeycomb CCD”), wherein a light-receiving portion is disposed at a position half a pixel pitch deviated in horizontal and vertical directions from a certain adjacent light-receiving portion, i.e., pixel arrangement of the light-receiving portions is made honeycomb-like, is used as a solid state imaging device. Detailed constitution of this honeycomb CCD is disclosed in, for example, JP-A-10-136391.

A light-receiving portion 105 is disposed in a state half a pixel pitch deviated from the adjacent image-receiving portions in horizontal and vertical directions. That is, adjacent light-receiving portions are respectively disposed at centers of a tetragonal lattice formed in the horizontal and vertical directions with respect to a certain light-receiving portion. Thus, an imaging region is constituted wherein light-receiving portions are disposed in such state that a tetragonal lattice having a pitch 1/√2 of the pixel pitch in the horizontal and vertical directions is inclined 45°.

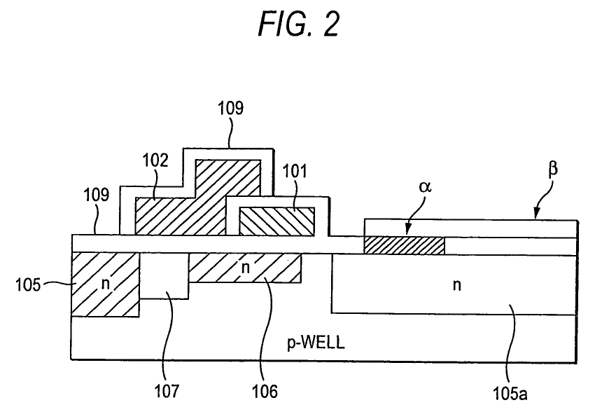

These light-receiving portions 105 are formed later. A signal charge-accumulating portion is provided at the position of this light-receiving portion. In a related imaging device, a buried photodiode comprising a P-type low concentration impurity region (P-well), an n-type high concentration impurity layer 105a and a surface P-type high concentration impurity layer 105b is formed as shown in FIG. 1 (B). In the invention, however, P-type high concentration impurity layer 105b is not formed, and the lower electrode of the light-receiving portion is directly connected to an n-type high concentration impurity layer 105a. That is, as is shown in FIG. 2, a plug α and lower electrode β are formed on the n-type high concentration impurity layer 105a in the latter stage of a substrate-forming process. As the lower electrode, A1 is used. Additionally, other processes are analogous to the case of forming a related CCD imaging device. That is, in the region adjacent to the light-receiving portions 105, charge transfer channels 106 containing an impurity at a higher concentration and capable of transferring charge accumulated in the light-receiving portions 105 are disposed in a vertical direction (column direction in the figure) stretching in a zigzag pattern. On the charge transfer channels 106 are formed transfer electrodes 111, 112, 113 and 114 comprising a 2-layered polysilicon electrode composed of a first layer 101 and a second layer 102. The 2-layered polysilicon electrode is formed by forming the first layer 101, then forming the second layer 102 via an insulating membrane 109 in such manner that end portions superpose on each other. These transfer electrodes 111, 112, 113 and 114 enable the whole pixels to be read by driving the charge transfer channels 106 through application of, for example, 4-phase pulses of φ1, φ2, φ3 and φ4.

On one side of the outer periphery of the light-receiving portions 105 are provided read-out gates 107 for reading the charge accumulated by photoelectric conversion to the charge transfer channels 106, and on the other side thereof are formed in a depth direction element-separating regions (channel stop) 108 comprising a P-type high concentration impurity for stopping charge transfer to the adjacent pixel row charge transfer channel. Also, on the light-receiving portions 105 and the surfaces of charge transfer channels 106, the first layer polysilicon electrode 101 and the second layer polysilicon electrode 102 are formed, respectively, an insulating membrane 109 of an oxide film such as SiO₂, and they are electrically insulated from each other by this insulating membrane 109.

With such honeycomb CCD, reading all pixels can be conducted even when the transfer electrode is of 2-layered polysilicon structure, which serves to simplify production processes. Also, 4 electrodes can be disposed per pixel. In this case, charge amount to be handled can be increased by driving with 4-phase transfer pulses about 1.5 times as much as the case of 3-phase driving. In comparison with a related tetragonal lattice CCD, the honeycomb structured CCD can have light-receiving areas with a comparatively large area and shows a higher resolution in both horizontal and vertical directions. Hence, even when images are made finer (higher density and more pixels), a highly sensitive solid state imaging device can be obtained.

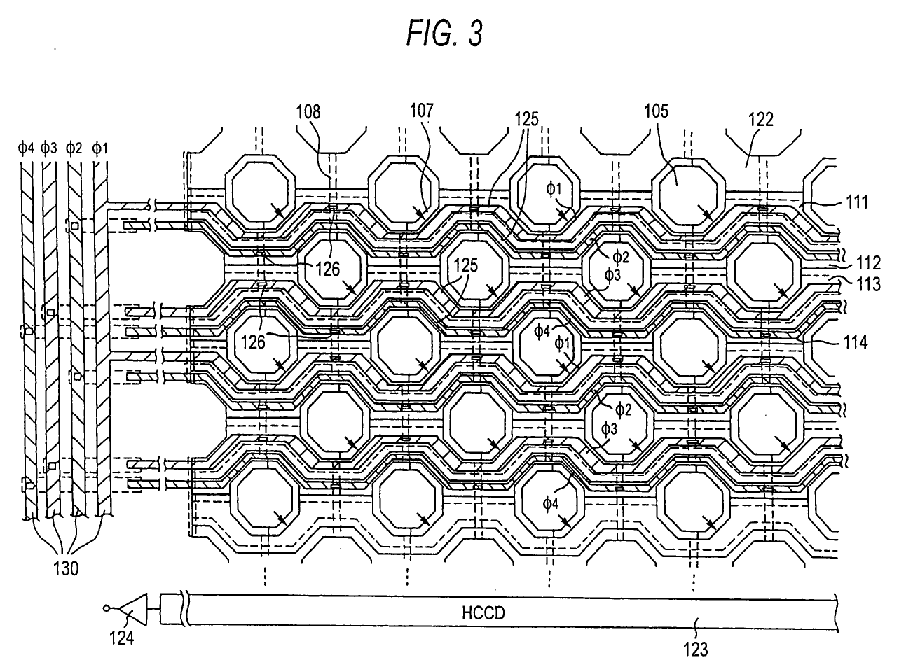

FIG. 3 is a plane view showing the constitution of the solid state imaging device in accordance with the embodiment of the invention. In the honeycomb CCD in this embodiment, the image-receiving portions 105 and the vertical charge transfer portions (VCCD) 112 comprising adjacent charge transfer channels 106 and transfer electrodes 111 to 114 are disposed in a two-dimensional plane state. One horizontal pixel row in the light-receiving portions 105 is shifted in the horizontal direction relative to the adjacent pixel row by ½ of the pitch of horizontal pixels, and one vertical pixel column is shifted in the vertical direction (column direction) relative to the adjacent pixel column by ½ of the pitch of vertical pixels, thus a so-called honeycomb arrangement being constituted. VCCD 122 is provided with transfer electrodes 111 to 114 for feeding 4-phase transfer pulses φ1 to φ4. Each of the transfer electrodes 111 to 114 extends in the horizontal direction (transverse direction) in a zigzag pattern so as to avoid the light-receiving portions 105.

Signal charges generated in the light-receiving portions 105 upon reception of incident light are read from the read-out gate 107 provided on the right and downward side in the figure to the charge transfer channel 106. The charge transfer channels 106 adjacent to the light-receiving portions of respective pixels are connected to each other from the upper part to the lower part in the figure and stretch in the vertical direction (column direction) in a zigzag pattern weaving between the light-receiving portions 105, thus forming VCCD 122 together with the transfer electrodes 111 to 114. Ends of respective VCCD are connected to light-shielded horizontal charge transfer portions 123 (HCCD). Further, the end of HCCD 123 is connected to a signal-reading circuit 124 having a floating diffusion amplifier (FDA), and the signal charges are read out of the CCD element by the signal-reading circuit.

In this embodiment, in order to reduce the electric resistance of the polysilicon electrodes used as the transfer electrodes 111 to 114 of VCCD, an electrode material having a smaller specific resistance than polysilicon, such as Al (aluminum) or W (tungsten), is laminated as metal wiring 125 on the polysilicon electrode via an insulating membrane to form a so-called metal-backed structure. This metal wiring 125 is electrically connected to each of the transfer electrodes 111 to 114 through contact holes 126. In the honeycomb CCD as in this embodiment, the metal wiring 125 can be disposed corresponding to the transfer electrodes 111 to 114 for all phases (layers) along the longitudinal direction of the 2-layered polysilicon electrodes, i.e., along the transverse direction in the figure in a zigzag pattern, as is different from the related tetragonal lattice CCD.

This metal wiring 125 extends in the transverse direction in the figure, and its ends are electrically connected to wiring pattern 130 for transferring the transfer pulses φ1 to φ4 fed from outside the element for driving. In the example shown by FIG. 3, a constitution is shown wherein metal wiring 125 and wiring pattern 130 are formed by A1, the portion at which the metal wiring 125 and other-phase wiring pattern 130 cross is formed by forming the wiring pattern 130 on the polysilicon electrode via an insulating membrane, and the metal wiring 125 and the wiring pattern 130 are electrically connected to the polysilicone electrode at the contact portion.

As the electrode material, Al, W, Cu (copper), Ti (titanium), Co (cobalt), Ni (nickel), Pd (palladium), Pt (platinum), or the nitrides thereof (WSi (tungsten silicide), etc.), silicides (TiSi (titanium silicide), etc.), alloys, compounds and composites are suited. A1 can be easily processable and can be handled with ease, and has a small electric resistance, and hence it is often used as a backing metal wiring. W less forms an alloy between polysilicon in comparison with Al, and hence it scarcely causes potential shift (partial change in potential) due to formation of alloy, and permits charge transfer with a good efficiency in VCCD. W is used as a light-shielding membrane for a solid state imaging device, and it may be used both for the metal wiring and for the light-shielding portion.

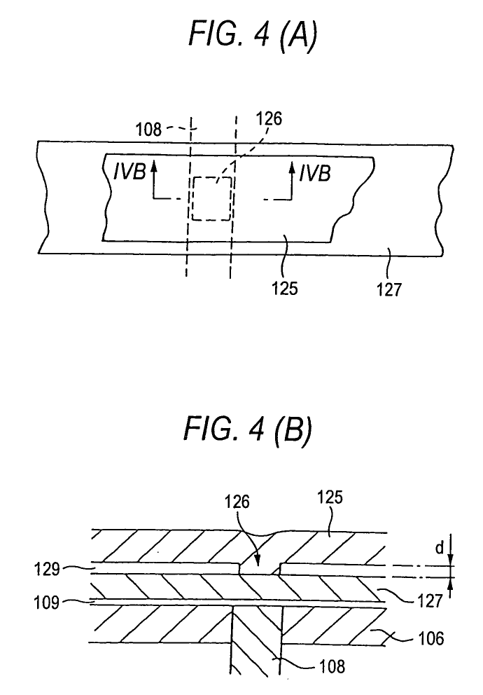

FIG. 4 is a view showing the constitution of a contact hole portion in the embodiment, with (A) being a plane, and (B) being a cross-sectional view. In this embodiment, contact holes 126 are provided on the channel stops 108 functioning as an element-separating region for separating the charge transfer channels 106 by the vertical pixel rows, with the polysilicon electrodes 127 and metal wirings 125 being electrically connected to each other by the contact holes 126. An insulating membrane 129 of SiO₂ is provided between the metal wiring 125 and the polysilicon electrode 127, with the thickness of the insulating membrane being 0.2 μm or less. The contact hole 126 is formed so that it penetrates through the insulating membrane 129 to electrically connect the metal wiring 125 to the polysilicon electrode 127.

In the honeycomb CCD like this embodiment, a large space region exists above the polysilicon electrodes 127, and hence, in comparison with tetragonal lattice CCD, position of the contact hole 126 can be decided in a wider range, thus the contact holes being easily formed on the electron-separating region. Also, an increase of unavailable region due to the contact hole 126 can be prevented by providing it on the channel stop 108. Further, one contact hole 126 can be provided per pixel in the horizontal direction (transverse direction) relative to each phase (layer) polysilicon electrode 127. Described above is the process for forming the charge transfer portion substrate.

The photodetectors A1 to A7, B1 to B7, C1 to C7, D1 to D7, E1 to E7 and F1 to F6 described in Examples 1 to 6 were formed on the lower electrode β on the above-mentioned substrate by completely reversing the organic layers to obtain respective imaging devices. As a result of determining the quantum efficiency of these imaging devices, the same tendency as in Example 1 were obtained.

### INDUSTRIAL APPLICABILITY

The invention provides a photodetector, which can be easily formed on any substrate, and shows a high quantum efficiency, and an imaging device excellent in the usability of the lights, having a number of photoelectric converting portions and a number of pixels.

The entire disclosure of each and every foreign patent application from which the benefit of foreign priority has been claimed in the present application is incorporated herein by reference, as if fully set forth.

1. A photodetector comprising:
at least one electron transporting organic material; and
at least one hole transporting material,
wherein said at least one electron transporting organic material has an ionization potential of more than 5.5 eV.

2. A photodetector comprising:
at least one electron transporting organic material; and
at least one hole transporting material,
wherein an ionization potential of said at least one electron transporting organic material is larger than an energy necessary for the highest-level electron of said at least one hole transporting material to be taken out to a vacuum infinite far point.

3. The photodetector according to claim 2,
wherein said at least one hole transporting material is at least one hole transporting organic material,
wherein an ionization potential of said at least one electron transporting organic material is more than an ionization potential of said at least one hole transporting organic material.

4. The photodetector according to claim 1,
wherein the ionization potential of said at least one electron transporting organic material is more than 6.0 eV.

5. The photodetector according to claim 1,
wherein said at least one electron transporting organic material is a compound represented by formula (I):
LA)ₘ Formula (I)
wherein m represents an integer of 2 or more;
L represents a linking group; and
each of A's independently represents a hetero ring group where at least two aromatic hetero rings are condensed to each other, and A's are the same or different.

6. The photodetector according to claim 1,
wherein said at least one electron transporting organic material is a compound represented by formula (III): 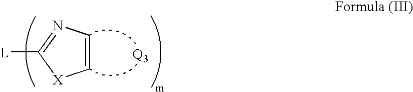
wherein m represents an integer of 2 or more;
L represents a linking group;
each of X's independently represents O, S, Se, Te or N—R;
R represents a hydrogen atom, an aliphatic hydrocarbon group, an aryl group or a hetero ring group; and
each of Q₃'s independently represents an atomic group necessary for forming an aromatic hetero ring.

7. The photodetector according to claim 1,
wherein said at least one electron transporting organic material is a compound represented by formula (V): 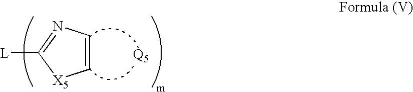
wherein m represents an integer of 2 or more;
L represents a linking group;
each of X₅'s independently represents O, S or N—R;
R represents a hydrogen atom, an aliphatic hydrocarbon group, an aryl group or a hetero ring group; and
each of Q₅'s independently represents an atomic group necessary for forming a 6-membered nitrogen-containing aromatic hetero ring.

8. The photodetector according to claim 1,
wherein said at least one electron transporting organic material is a compound represented by formula (VII): 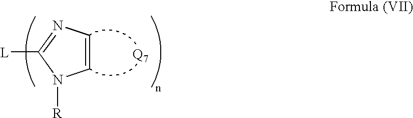
wherein n represents an integer of 2 to 8;
L represents a linking group;
each of R's independently represents a hydrogen atom, an aliphatic hydrocarbon group, an aryl group or a hetero ring group; and
each of Q₇'s independently represents an atomic group necessary for forming a 6-membered nitrogen-containing aromatic hetero ring.

9. The photodetector according to claim 1,
wherein said at least one electron transporting organic material is a compound represented by formula (VIII): 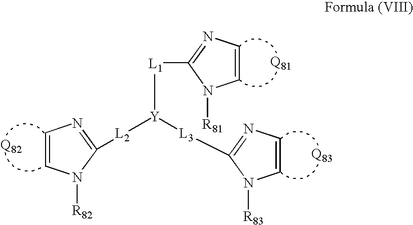
wherein Q₈₁, Q₈₂ and Q₈₃ each independently represents an atomic group necessary for forming a 6-membered nitrogen-containing aromatic hetero ring;
R₈₁, R₈₂ and R₈₃ each independently represents a hydrogen atom, an aliphatic hydrocarbon group, an aryl group or a hetero ring group;
L₁, L₂ and L₃ each independently represents a linking group; and
Y represents a nitrogen atom or a 1,3,5-benzenetriyl group.

10. The photodetector according to claim 1,
wherein said at least one electron transporting organic material is a compound represented by formula (IX): 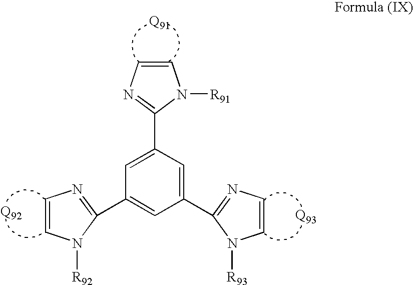
wherein Q₉₁, Q₉₂ and Q₉₃ each independently represents an atomic group necessary for forming a 6-membered nitrogen-containing aromatic hetero ring; and
R₉₁, R₉₂ and R₉₃ each independently represents a hydrogen atom, an aliphatic hydrocarbon group, an aryl group or a hetero ring group.

11. The photodetector according to claim 1,
wherein said at least one electron transporting organic material is a compound represented by formula (XI): 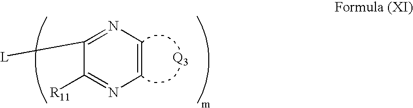
wherein m represents an integer of 2 or more;
L represents a linking group;
each of Q₃'s independently represents an atomic group necessary for forming an aromatic hetero ring group; and
each of R₁₁'s independently represents a hydrogen atom or a substituent.

12. The photodetector according to claim 1, further comprising:
at least one transparent electrode; and
at least one electrode,
wherein said at least one electron transporting organic material is interposed between said at least one transparent electrode and said at least one electrode.

13. The photodetector according to claim 1, further comprising:
at least one transparent electrode; and
at least one electrode,
wherein said at least one electron transporting organic material and said at least one hole transporting material are interposed between said at least one transparent electrode and said at least one electrode.

14. The photodetector according to claim 3, further comprising:
at least one transparent electrode; and
at least one electrode,
wherein said at least one electron transporting organic material and said at least one hole transporting organic material are interposed between said at least one transparent electrode and said at least one electrode.

15. The photodetector according to claim 1,
wherein said at least one electron transporting organic material is deposited in vacuum.

16. The photodetector according to claim 3,
wherein at least one of said at least one electron transporting organic material and said at least one hole transporting organic material is deposited in vacuum.

17. An imaging device comprising a photodetector according to claim 1.

18. The imaging device according to claim 17, further comprising:
a substrate;
a first layer comprising a first photodetector; and
a second layer comprising a second photodetector.

19. The imaging device according to claim 17, further comprising:
a substrate;
a first layer comprising a first photodetector;
a second layer comprising a second photodetector; and
a third layer comprising a third photodetector.

20. The imaging device according to claim 19,
wherein the first photodetector comprises a blue light photodetector; the second photodetector comprises a green light photodetector; and the third photodetector comprises a red light photodetector.
